(19) United States
(12) Patent Application Publication
(10) Pub. No.: US 2020/0174364 A1
(43) Pub. Date: Jun. 4, 2020

(54) CURABLE COMPOSITION, FILM, INFRARED TRANSMITTING FILTER, SOLID IMAGE PICKUP ELEMENT, AND OPTICAL SENSOR

(71) Applicant: FUJIFILM Corporation, Tokyo (JP)

(72) Inventor: Masahiro MORI, Haibara-gun (JP)

(73) Assignee: FUJIFILM Corporation, Tokyo (JP)

(21) Appl. No.: 16/784,672

(22) Filed: Feb. 7, 2020

Related U.S. Application Data
(63) Continuation of application No. PCT/JP2018/032829, filed on Sep. 5, 2018.

(30) Foreign Application Priority Data
Sep. 25, 2017 (JP) 2017-183374

(51) Int. Cl. G03F 7/00; G03F 7/027; C09D 4/00; C09D 5/32; G02B 5/20

(52) U.S. Cl. CPC G03F 7/0007; G03F 7/027; G02B 5/208; C09D 5/32; C09D 4/00

(57) ABSTRACT

A curable composition includes a coloring material and a curable compound, a content of a compound in which a ratio of an absorbance at a wavelength of 365 nm to a maximum absorbance in a wavelength range of 420 to 1000 nm is 0.6 or lower in the coloring material is 95 mass % or higher, a content of the coloring material in the curable composition is 20 to 70 mass % with respect to a total solid content of the curable composition, a ratio of a minimum absorbance in a wavelength range of 300 to 380 nm to a minimum absorbance in a wavelength range of 420 to 650 nm is 0.8 or lower, and a ratio of the minimum absorbance in a wavelength range of 420 to 650 nm to a maximum absorbance of the curable composition in a wavelength range of 1000 to 1300 nm is 4.5 or higher.

### CROSS-REFERENCE TO RELATED APPLICATIONS

This application is a Continuation of PCT International Application No. PCT/JP2018/032829 filed on Sep. 5, 2018, which claims priority under 35 U.S.C § 119(a) to Japanese Patent Application No. 2017-183374 filed on Sep. 25, 2017. Each of the above application(s) is hereby expressly incorporated by reference, in its entirety, into the present application.

### BACKGROUND OF THE INVENTION

### 1. Field of the Invention

The present invention relates to a curable composition and a film suitable for producing an infrared transmitting filter and the like. The present invention also relates to an infrared transmitting filter, a solid image pickup element using the infrared transmitting filter, and an optical sensor using the infrared transmitting filter.

### 2. Description of the Related Art

A solid image pickup element is used as an optical sensor in various applications. For example, infrared light is less likely to be scattered than visible light due to its longer wavelength and can be used in, for example, distance measurement or three-dimensional measurement. In addition, infrared light is invisible to humans, animals, or the like. Therefore, even in a case where a subject is irradiated with infrared light using an infrared light source at night, the subject cannot recognize the infrared light. Thus, infrared light can be used for imaging a nocturnal wild animal or imaging a subject without provoking the subject for security reasons. In this way, an optical sensor that detects infrared light can be used in various applications, and the development of a film that can block visible light and allow transmission of infrared light has been considered (for example, refer to WO2016/190162A, JP2016-177079A, JP2016-177273A, and WO2014/208348A).

On the other hand, JP2015-525260A discloses a black colorant mixture including a bis-oxodihydro-indolylene-benzodifuranone colorant and a perylene colorant. In addition, JP2015-525260A discloses that the black colorant mixture is used as, for example, a black matrix for a color filter, a black column spacer for a liquid crystal display device, or a black bezel of a display device.

### SUMMARY OF THE INVENTION

In this way, recently, various investigations were conducted on the film that blocks visible light and allows transmission of infrared light.

On the other hand, recently, it has been attempted to perform sensing or imaging using both infrared light and ultraviolet light. However, it was found that films which have been known until now, for example, the films disclosed in WO2016/190162A, JP2016-177079A, JP2016-177273A, and WO2014/208348A have low transmittance with respect to ultraviolet light. In this way, in the films which have been known until now, it is difficult to allow transmission of ultraviolet light and infrared light in a state where visible light is blocked so that noise derived from visible light is small.

In addition, in the invention disclosed in JP2015-525260A, similarly, it is difficult to allow transmission of ultraviolet light and infrared light in a state where visible light is blocked so that noise derived from visible light is small.

Accordingly, an object of the present invention is to provide a curable composition of which a film capable of allowing transmission of ultraviolet light and infrared light in a state where noise derived from visible light is small can be formed. Another object of the present invention is to provide a film, an infrared transmitting filter, a solid image pickup element, and an optical sensor.

As a result of detailed investigation, the present inventors found that the objects can be achieved using a curable composition described below, thereby completing the present invention. That is, the present invention is as follows.

<1> A curable composition comprising:

a coloring material; and

a curable compound,

in which a ratio A/B of a minimum value A of an absorbance of the curable composition in a wavelength range of 300 to 380 nm to a minimum value B of an absorbance of the curable composition in a wavelength range of 420 to 650 nm is 0.8 or lower,

a ratio B/C of the minimum value B of the absorbance of the curable composition in a wavelength range of 420 to 650 nm to a maximum value C of an absorbance of the curable composition in a wavelength range of 1000 to 1300 nm is 4.5 or higher,

a content of a compound in which a ratio D1/D2 of an absorbance D1 at a wavelength of 365 nm to a maximum value D2 of an absorbance in a wavelength range of 420 to 1000 nm is 0.6 or lower in the coloring material is 95 mass % or higher with respect to a total mass of the coloring material,

a content of the coloring material is 20 to 70 mass % with respect to a total solid content of the curable composition.

<2> The curable composition according to <1>,

in which a content of a phthalocyanine compound is 5 mass % or lower with respect to the total mass of the coloring material.

<3> The curable composition according to <1> or <2>,

in which a content of a blue colorant is 5 mass % or lower with respect to the total mass of the coloring material.

<4> The curable composition according to any one of <1> to <3>,

in which the coloring material includes one or more colors of chromatic colorants.

<5> The curable composition according to any one of <1> to <4>,

in which the coloring material includes a red colorant.

<6> The curable composition according to any one of <1> to <5>,

in which the coloring material includes a perylene compound.

<7> The curable composition according to any one of <1> to <6>,

in which the coloring material includes a near infrared absorbing colorant.

<8> The curable composition according to any one of <1> to <7>, further comprising:

a polymerizable compound; and

a photopolymerization initiator.

<9> A film comprising:

20 to 70 mass % of a coloring material,

in which a content of a compound in which a ratio D1/D2 of an absorbance D1 at a wavelength of 365 nm to a maximum value D2 of an absorbance in a wavelength range of 420 to 1000 nm is 0.6 or lower in the coloring material is 95 mass % or higher with respect to a total mass of the coloring material,

a maximum value of a transmittance in a wavelength range of 300 to 380 nm is 10% or higher,

a maximum value of a transmittance in a wavelength range of 420 to 650 nm is 20% or lower, and

a maximum value of a transmittance in a wavelength range of 1000 to 1300 nm is 70% or higher.

<10> A film which is obtained using the curable composition according to any one of <1> to <8>.

<11> An infrared transmitting filter comprising:

the film according to <9> or <10>.

<12> A solid image pickup element comprising:

the film according to <9> or <10>.

<13> An optical sensor comprising:

the film according to <9> or <10>.

According to the present invention, it is possible to provide a curable composition of which a film capable of allowing transmission of ultraviolet light and infrared light in a state where noise derived from visible light is small can be formed. In addition, it is possible to provide a film, an infrared transmitting filter, a solid image pickup element, and an optical sensor.

### BRIEF DESCRIPTION OF THE DRAWINGS

FIG. 1 is a schematic cross-sectional view showing a configuration of an embodiment of an optical sensor according to the present invention.

### DESCRIPTION OF THE PREFERRED EMBODIMENTS

In the present specification, a total solid content denotes the total content of components excluding a solvent from the entire composition.

In the present specification, unless specified as a substituted group or as an unsubstituted group, a group (atomic group) denotes not only a group having no substituent but also a group having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV light), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in a chemical formula, Me represents a methyl group, Et represents an ethyl group, Pr represents a propyl group, Bu represents a butyl group, and Ph represents a phenyl group.

In the present specification, the term “step” denotes not only an individual step but also a step which is not clearly distinguishable from another step as long as an effect expected from the step can be achieved.

In the present specification, a weight-average molecular weight and a number-average molecular weight are defined as values in terms of polystyrene measured by gel permeation chromatography (GPC). In this specification, an weight-average molecular weight (Mw) and a number-average molecular weight (Mn) can be obtained by using HLC-8220 (manufactured by Tosoh Corporation), using TSKgel Super AWM-H (manufactured by Tosoh Corporation; 6.0 mm ID (inner diameter)×15.0 cm) as a column, and using a 10 mmol/L lithium bromide N-methylpyrrolidinone (NMP) solution as an eluent.

A pigment used in the present invention denotes an insoluble colorant compound which is not likely to dissolve in a solvent. Typically, a pigment denotes a colorant compound which is present in a state of being dispersed as particles in a composition. As the solvent described herein, for example, an arbitrary solvent can be used, and examples thereof include a solvent described in column of solvent mentioned later. It is preferable that the pigment used in the present invention has a solubility of 0.1 g/100 g Solvent or lower at 25° C., for example, both in propylene glycol monomethyl ether acetate and in water.

<Curable Composition>

A curable composition according to an embodiment of the present invention comprises: a coloring material; and a curable compound, a ratio A/B of a minimum value A of an absorbance of the curable composition in a wavelength range of 300 to 380 nm to a minimum value B of an absorbance of the curable composition in a wavelength range of 420 to 650 nm is 0.8 or lower, a ratio B/C of the minimum value B of the absorbance of the curable composition in a wavelength range of 420 to 650 nm to a maximum value C of an absorbance of the curable composition in a wavelength range of 1000 to 1300 nm is 4.5 or higher, a content of a compound in which a ratio D1/D2 of an absorbance D1 at a wavelength of 365 nm to a maximum value D2 of an absorbance in a wavelength range of 420 to 1000 nm is 0.6 or lower in the coloring material is 95 mass % or higher with respect to a total mass of the coloring material, and a content of the coloring material is 20 to 70 mass % with respect to a total solid content of the curable composition.

With the curable composition according to the embodiment of the present invention, a film having spectral characteristics in which a maximum value of a transmittance in a wavelength range of 300 to 380 nm is 10% or higher, a maximum value of a transmittance in a wavelength range of 420 to 650 nm is 20% or lower, and a maximum value of a transmittance in a wavelength range of 1000 to 1300 nm is 70% or higher can be suitably formed. Therefore, the film formed of the curable composition according to the embodiment of the present invention can allow transmission of ultraviolet light and infrared light in a state where noise derived from visible light is small.

In addition, in the curable composition according to the embodiment of the present invention, the value of the absorbance ratio A/B is 0.8 or lower. Therefore, transmittance with respect to light (for example, i-rays) used for exposure is high. Therefore, in a case where the curable composition according to the embodiment of the present invention includes a polymerizable compound as the curable compound and a photopolymerization initiator, the film can be cured up to a bottom portion (support side) by exposure, and adhesiveness of the obtained film with a support can be further improved.

The condition of the absorbance may be achieved by any means, but can be suitably achieved by adjusting the type and the content of the coloring material.

Regarding the spectral characteristics of the curable composition according to the embodiment of the present invention, the value of the above-described absorbance ratio A/B is preferably 0.7 or lower and more preferably 0.6 or lower. The lower limit may be 0. In addition, the value of the above-described absorbance ratio B/C is preferably 10 or higher, more preferably 20 or higher, still more preferably 30 or higher, and still more preferably 35 or higher. The upper limit is, for example, preferably 200 or lower and more preferably 90 or lower.

An absorbance Aλ at a wavelength X is defined by the following formula (1).

Aλ=−log(Tλ/100) (I)

Aλ is an absorbance at the wavelength λ and Tλ is a transmittance (%) at the wavelength λ.

In the present invention, the value of the absorbance may be a value measured in the form of a solution, or may be a value measured in the form of a film formed using the curable composition according to the embodiment of the present invention. In a case of measuring the absorbance in the form of a film, it is preferable that the value is measured by using a film formed using a method including: applying the curable composition to a glass substrate using a method such as spin coating such that a thickness of the film after drying is a predetermined thickness; and drying the curable composition using a hot plate at 100° C. for 120 seconds. The thickness of the film can be obtained by measuring the thickness of the substrate including the film using a stylus surface profilometer (DEKTAK 150, manufactured by ULVAC Inc.).

A method of measuring the spectral characteristics and the thickness of the film formed using the curable composition according to the embodiment of the present invention is as follows.

The curable composition according to the embodiment of the present invention is applied to a glass substrate using a method such as spin coating such that the thickness of the film after drying is a predetermined value, and then is dried using a hot plate at 100° C. for 120 seconds. The thickness of the film is obtained by measuring the thickness of the substrate after drying, which includes the film, using a stylus surface profilometer (DEKTAK 150, manufactured by ULVAC Inc.). The transmittance of the dried substrate including the film is measured in a wavelength range of 300 to 1300 nm using a spectrophotometer (U-4100, manufactured by Hitachi High-Technologies Corporation).

In addition, it is more preferable that the curable composition according to the embodiment of the present invention satisfies any one of the following spectral characteristics (IR1) to (IR3).

(IR1) A ratio A1/B1 of a minimum value A1 of an absorbance in a wavelength range of 300 to 380 nm to a minimum value B1 of an absorbance in a wavelength range of 420 to 650 nm is 0.8 or lower (preferably 0.7 or lower and more preferably 0.6 or lower), and a ratio B1/C1 of the minimum value B1 of the absorbance in a wavelength range of 420 to 650 nm to a maximum value C1 of an absorbance in a wavelength range of 800 to 1300 nm is 4.5 or higher (preferably 10 or higher, more preferably 20 or higher, and still more preferably 30 or higher). According to this aspect, a film that can block light in a wavelength range of 420 to 650 nm and can allow transmission of light in a wavelength range of 300 to 380 nm and light in a wavelength of longer than 750 nm can be formed.

(IR2) A ratio A2/B2 of a minimum value A2 of an absorbance in a wavelength range of 300 to 380 nm to a minimum value B2 of an absorbance in a wavelength range of 420 to 750 nm is 0.8 or lower (preferably 0.7 or lower and more preferably 0.6 or lower), and a ratio B2/C2 of the minimum value B2 of the absorbance in a wavelength range of 420 to 750 nm to a maximum value C2 of an absorbance in a wavelength range of 900 to 1300 nm is 4.5 or higher (preferably 10 or higher, more preferably 20 or higher, and still more preferably 30 or higher). According to this aspect, a film that can block light in a wavelength range of 420 to 750 nm and can allow transmission of light in a wavelength range of 300 to 380 nm and light in a wavelength of longer than 850 nm can be formed.

(IR3) A ratio A3/B3 of a minimum value A3 of an absorbance in a wavelength range of 300 to 380 nm to a minimum value B3 of an absorbance in a wavelength range of 420 to 830 nm is 0.8 or lower (preferably 0.7 or lower and more preferably 0.6 or lower), and a ratio R3/C3 of the minimum value 133 of the absorbance in a wavelength range of 420 to R30 nm to a maximum value C3 of an absorbance in a wavelength range of 1000 to 1300 nm is 4.5 or higher (preferably 10 or higher, more preferably 20 or higher, and still more preferably 30 or higher). According to this aspect, a film that can block light in a wavelength range of 420 to 830 nm and can allow transmission of light in a wavelength range of 300 to 380 nm and light in a wavelength of longer than 900 nm can be formed.

The curable composition according to the embodiment of the present invention can also be referred to as an infrared transmitting composition because it allows transmission of infrared light. Hereinafter, each component which can constitute the curable composition according to the embodiment of the present invention will be described.

<<Coloring Material>>

The curable composition according to the embodiment of the present invention includes a coloring material. The content of the coloring material is 20 to 70 mass % with respect to the total solid content of the curable composition. The lower limit is preferably 30 mass % or higher, more preferably 40 mass % or higher, and still more preferably 50 mass % or higher. The upper limit is preferably 65 mass % or lower, and more preferably 60 mass % or lower.

In addition, the content of a compound in which a ratio D1/D2 of an absorbance D1 at a wavelength of 365 nm to a maximum value D2 of an absorbance in a wavelength range of 420 to 1000 nm is 0.6 or lower in the coloring material used in the present invention is 95 mass % or higher, preferably 96 mass % or higher, and more preferably 97 mass % or higher with respect to the total mass of the coloring material. The value of the above-described absorbance ratio D1/D2 of the above-described compound is preferably 0.5 or lower, more preferably 0.4 or lower, and still more preferably 0.3 or lower. The absorbance of the coloring material used in the present invention is a value in the film. The absorbance of the coloring material is a value calculated by forming a film in which the content of the coloring material as a measurement target is 50 mass % using a composition including the coloring material as a measurement target and any resin and measuring an absorbance of the above-described film in a wavelength range of 300 to 1300 nm. Examples of a measuring device include a spectrophotometer U-4100 (manufactured by Hitachi High-Technologies Corporation). The thickness of the film can be freely selected and, for example, may be 0.5 μm.

Examples of the compound in which the above-described absorbance ratio D1/D2 is 0.6 or lower include compounds described in columns of a red colorant, a yellow colorant, a violet colorant, an orange colorant, an organic black colorant, a near infrared absorbing colorant described below. The above-described compounds may be a pigment or a dye. As the pigment, an organic pigment is preferable.

Examples of the organic pigment include:

red pigments such as C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279;

yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214;

orange pigments such as C. I. Pigment Orange 2, 5, 1c3, 16, 17:1, 31, 34, 36, 38, 43, 46, 48, 49, 51, 52, 55, 59, 60, 61, 62, 64, 71, and 73; and

violet pigments such as C. I. Pigment Violet 1, 19, 23, 27, 32, 37, and 42.

As the dye, well-known dyes can be used without any particular limitation. For example, dyes having a chemical structure of a pyrazole azo, an anilino azo, a triarylmethane, an anthraquinone, an anthrapyridone, a benzylidene, an oxonol, a pyrazolotriazole azo, a pyridone azo, a cyanine, a phenothiazine, a pyrrolopyrazole azomethine, a xanthene, a benzopyran, an indigo, a pyrromethene, or the like can be used. In addition, a multimer of the above-described dyes may be used. In addition, dyes described in JP2015-028144A and JP2015-034966A can also be used.

Examples of the organic black colorant include an azomethine compound, a perylene compound, and an azo compound. Among these, a perylene compound is preferable. Examples of the azomethine compound include compounds described in JP1989-17060IA (JP-H01-170601A) and JP1990-034664A (JP-H02-034664A). As a commercially available product, “Chromofine Black A 1103” (manufactured by Dainichiseika Color & Chemicals Mfg. Co., Ltd.) is available.

Examples of the perylene compound include compounds represented by Formulae (Per1) to (Per3).

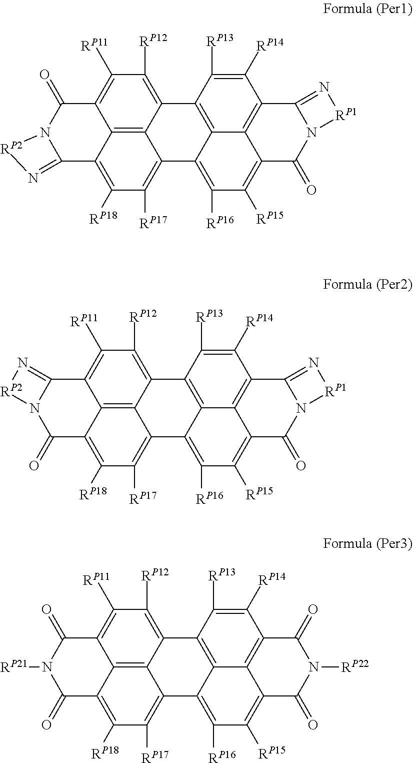

In the formulae, R^{P1} and R^{P2} each independently represent phenylene, naphthylene, and pyridylene.

The phenylene, naphthylene, and pyridylene represented by R^{P1} and R^{P2} may be unsubstituted or may have a substituent. Examples of the substituent include a halogen atom, a cyano group, a nitro group, an alkyl group, an alkenyl group, an alkynyl group, an aralkyl group, an aryl group, a heteroaryl group, —OR^{P101}, —COR^{P102}, —COOR^{P103}, —OCOR^{P104}, —NR^{P105}R^{P106}, —NHCOR^{P107}, —CONR^{P108}R^{P109}, —NHCONR^{P110}R^{P111}, —NHCONR^{P112}, —SR^{P113}, —SO₂R^{P114}, —SO₂OR^{P115}, —NHSO₂R^{P116}, and —SO₂NR^{P117}R^{P118}. Among these, an alkyl group, an alkoxy group, a hydroxy group, a nitro group, or a halogen atom is preferable. R^{P101} to R^{P118} each independently represent a hydrogen atom, an alkyl group, an alkenyl group, an alkynyl group, an aryl group, or a heteroaryl group. In a case where the above-described groups can be further substituted, the groups may further have a substituent. Examples of the substituent which may be further included include the above-described substituents.

R^{P11} to R^{P18} each independently represent a hydrogen atom or a substituent. Examples of the substituent represented by R^{P11} to R^{P18} include the above-described substituent. Among these, a halogen atom is preferable. As the halogen atom, F, Cl, and Br are preferable.

R^{P21} and R^{P22} each independently represent a substituent. Examples of the substituent represented by R^{P21} and R^{P22} include the above-described substituent. Among these, an aralkyl group is preferable. The aralkyl group may further have a substituent described above.

Specific examples of the perylene compound include compounds having the following structure. As the perylene compound, C.I. Pigment Black 31 and 32 can also be used.

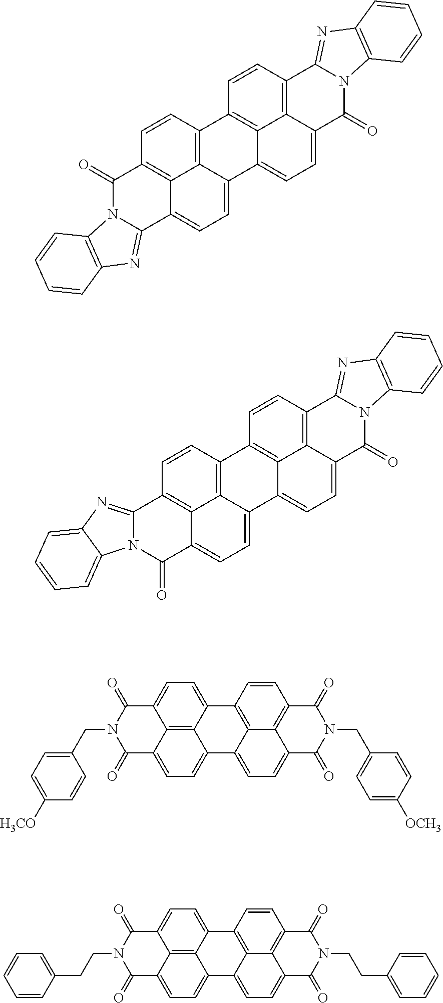 [SMILES: O=c1c2ccc3c4ccc5c6c(ccc(c7ccc(c2c37)c2nc3ccccc3n12)c46)c(=O)n1c2ccccc2nc51 ; O=c1c2ccc3c4ccc5c(=O)n6c7ccccc7nc6c6ccc(c7ccc(c2c37)c2nc3ccccc3n12)c4c56 ; COc1ccc(CN2C(=O)c3ccc4c5ccc6c7c(ccc(c8ccc(c3c48)C2=O)c75)C(=O)N(Cc2ccc(OC)cc2)C6=O)cc1 ; O=C1c2ccc3c4ccc5c6c(ccc(c7ccc(c2c37)C(=O)N1CCc1ccccc1)c64)C(=O)N(CCc1ccccc1)C5=O]

Examples of the compound in which the above-described absorbance ratio D1/D2 is higher than 0.6 include a phthalocyanine compound and a bisbenzofuranone compound. Examples of the phthalocyanine compound include an aluminum phthalocyanine compound, a copper phthalocyanine compound, a zinc phthalocyanine compound, and an oxytitanium phthalocyanine compound. In addition, Color Index (C. I.) Pigment Green 7, 36, 58, or 59 or C. I. Pigment Blue 15:1, 15:2, 15:3, 15:4, or 15:6 can also be used.

Examples of the bisbenzofuranone compound include a compound represented by the following formula. As a commercially available product of the bisbenzofuranone compound, for example, “IRAGAPHOR BLACK” (manufactured by BASF SE) is available. The content of the above-described compound is 5 mass % or lower, preferably 4 mass % or lower, more preferably 3 mass % or lower, and still more preferably substantially 0 mass % with respect to the total mass of the coloring material. In the present invention, substantially not containing the above-described compound represents that the content of the above-described compound is 0.5 mass % or lower, preferably 0.1 mass % or lower, and more preferably 0 mass % with respect to the total mass of the coloring material.

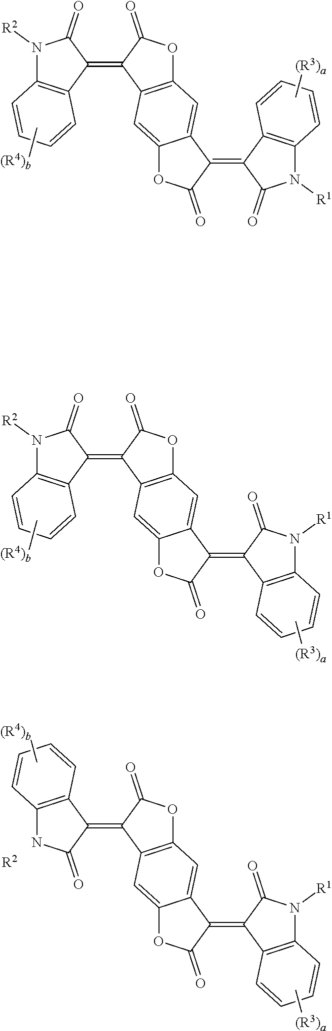

In the formulae, R¹ and R² each independently represent a hydrogen atom or a substituent, R³ and R⁴ each independently represent a substituent, a and b each independently represent an integer of 0 to 4, in a case where a is 2 or more, a plurality of R³'s may be the same as or different from each other, a plurality of R³'s may be bonded to each other to form a ring, in a case where b is 2 or more, a plurality of R⁴'s may be the same as or different from each other, and a plurality of R⁴'s may be bonded to each other to form a ring.

Examples of the substituent represented by R¹ to R⁴ include a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, NHCONR³¹⁰R³¹¹, NHCOOR³¹², —SR³¹³, —SO₂R¹¹⁴, —SO₂OR³¹⁵, —NHSO₂R³¹⁶, and —SO₂NR³¹⁷R³¹⁸. R³⁰¹ to R³¹⁸ each independently represent a hydrogen atom, an alkyl group, an alkenyl group, an alkynyl group, an aryl group, or a heteroaryl group. In a case where the above-described groups can be further substituted, the groups may further have a substituent.

In the coloring material used in the present invention, the content of the phthalocyanine compound is preferably 5 mass % or lower, more preferably 3 mass % or lower, still more preferably 1 mass % or lower, and particularly preferably substantially 0 mass % with respect to the total mass of the coloring material. In the present invention, substantially not containing the phthalocyanine compound represents that the content of the phthalocyanine compound is 0.5 mass % or lower, preferably 0.1 mass % or lower, and more preferably 0 mass % with respect to the total mass of the coloring material. The phthalocyanine compound is likely to have a large absorption in a wavelength range of 300 to 380 nm. Therefore, by reducing the content of the phthalocyanine compound with respect to the total mass of the coloring material, transmittance of the obtained film with respect to light in an ultraviolet range can be increased, and desired spectral characteristics can be easily achieved.

In the coloring material used in the present invention, the content of the blue colorant is preferably 5 mass % or lower, more preferably 3 mass % or lower, still more preferably 1 mass % or lower, and still more preferably substantially 0 mass % with respect to the total mass of the coloring material. In the present invention, substantially not containing the blue colorant represents that the content of the blue colorant is 0.5 mass % or lower, preferably 0.1 mass % or lower, and more preferably 0 mass % with respect to the total mass of the coloring material. The blue colorant is likely to have a large absorption in a wavelength range of 300 to 380 nm. Therefore, by reducing the content of the blue colorant with respect to the total mass of the coloring material, transmittance of the obtained film with respect to light in an ultraviolet range can be increased, and desired spectral characteristics can be easily achieved.

It is preferable that the coloring material used in the present invention includes one or more colors of chromatic colorants. According to this aspect, the light blocking properties of the obtained film with respect to light in a visible range can be further improved. As the chromatic colorant, a red colorant, a yellow colorant, a violet colorant, or an orange colorant is preferable, and including at least a red colorant is more preferable. In the present invention, “chromatic colorant” denotes a colorant other than a white colorant and a black colorant.

In a case where the curable composition according to the embodiment of the present invention includes a chromatic colorant, it is preferable that the content of the chromatic colorant is 20 to 80 mass % with respect to the total solid content of the curable composition. The upper limit is preferably 70 mass % or lower and more preferably 65 mass % or lower. The lower limit is preferably 30 mass % or higher and more preferably 40 mass % or higher.

In addition, it is preferable that the coloring material used in the present invention includes a perylene compound. The perylene compound is a compound having a small absorption in a wavelength range of 300 to 380 nm and an absorption in a visible range. Therefore, the light blocking properties of the obtained film with respect to light in a visible range can be further improved without deterioration in the transmittance of ultraviolet light. As the perylene compound, the compounds represented by Formula (Per1) to Formula (Per3) are preferable.

In a case where the curable composition according to the embodiment of the present invention includes a perylene compound, it is preferable that the content of the perylene compound is 5 to 60 mass % with respect to the total solid content of the curable composition. The upper limit is preferably 55 mass % or lower and more preferably 50 mass % or lower. The lower limit is preferably 10 mass % or higher and more preferably 15 mass % or higher. In addition, in a case where the curable composition according to the embodiment of the present invention includes a chromatic colorant and a perylene compound, the total content thereof is preferably 20 to 80 mass % with respect to the total solid content of the curable composition. The upper limit is preferably 70 mass % or lower and more preferably 65 mass % or lower. The lower limit is preferably 30 mass % or higher and more preferably 40 mass % or higher.

Preferable aspects of the coloring material used in the present invention are as follows.

(1) An aspect in which the coloring material includes a red colorant and an organic black colorant.

(2) An aspect in which the coloring material includes a red colorant, a violet colorant, and an organic black colorant.

(3) An aspect in which the coloring material includes a red colorant, a violet colorant, a yellow colorant, and an organic black colorant.

(4) An aspect in which the coloring material further includes a near infrared absorbing colorant in any one of the aspects (1), (2), or (3).

In the above-described aspects (1), (2), and (3), a curable composition satisfying the above-described spectral characteristics (IR2) can be easily obtained. In the above-described aspect (4), a curable composition satisfying the above-described spectral characteristics (IR3) can be easily obtained.

In the aspect (1), a mass ratio red colorant:organic black colorant between the red colorant and the organic black colorant is preferably 10 to 40:50 to 90, more preferably 25 to 35:55 to 85, and still more preferably 20 to 30:60 to 80.

In the aspect (2), a mass ratio red colorant:violet colorant:organic black colorant between the red colorant, the violet colorant, and the organic black colorant is preferably 1 to 20:1 to 20:50 to 95, more preferably 3 to 15:3 to 15:60 to 90, and still more preferably 5 to 10:5 to 10:70 to 85.

In the aspect (3), a mass ratio red colorant:violet colorant:yellow colorant:organic black colorant between the red colorant, the violet colorant, the yellow colorant, and the organic black colorant is preferably 1 to 20:1 to 20:1 to 20:50 to 95, more preferably 3 to 15:3 to 15:3 to 15:60 to 90, and still more preferably 5 to 10:5 to 10:5 to 10:70 to 85.

In the aspect (4), the content of the near infrared absorbing colorant is preferably 5 to 50 mass %, more preferably 10 to 45 mass %, and still more preferably 15 to 40 mass % with respect to the total mass of the coloring material.

The curable composition according to the embodiment of the present invention may include a near infrared absorbing colorant as the coloring material. In an infrared transmitting filter, the near infrared absorbing colorant has a function of limiting light to be transmitted (near infrared light) to a longer wavelength side.

In the present invention, as the near infrared absorbing colorant, a compound having a absorption maximum wavelength in a near infrared range (preferably a wavelength range of longer than 700 nm and 1000 nm or shorter) can be preferably used. In addition, as the near infrared absorbing colorant used in the present invention, the compound in which a ratio D1/D2 of an absorbance D1 at a wavelength of 365 nm to a maximum value D2 of an absorbance in a wavelength range of 420 to 1000 nm is 0.6 or lower is preferable. The near infrared absorbing colorant may be a pigment or a dye.

As the near infrared absorbing colorant, at least one selected from a pyrrolopyrrole compound, a cyanine compound, a squarylium compound, a quaterrylene compound, a merocyanine compound, a croconium compound, an oxonol compound, a diimmonium compound, a dithiol compound, a triarylmethane compound, a pyrromethene compound, an azomethine compound, or an anthraquinone compound, at least one selected from a pyrrolopyrrole compound, a cyanine compound, a squarylium compound, or a quaterrylene compound is more preferable, at least one selected from a pyrrolopyrrole compound, a cyanine compound, or a squarylium compound is still more preferable, and a pyrrolopyrrole compound or a squarylium compound is particularly preferable. Examples of the diimmonium compound include a compound described in JP2008-528706A, the content of which is incorporated herein by reference. In addition, as the cyanine compound, the diimmonium compound, and the squarylium compound, for example, a compound described in paragraphs “0010” to “0081” of JP2010-111750A may be used, the content of which is incorporated herein by reference. In addition, the details of the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. In addition, a compound described in JP2016-146619A can also be used as the near infrared absorbing colorant, the content of which is incorporated herein by reference.

As the pyrrolopyrrole compound, a compound represented by Formula (PP) is preferable

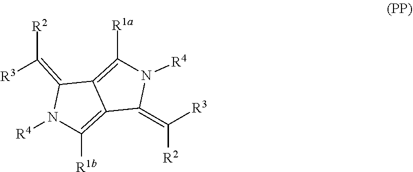

In the formula, R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, or a metal atom, R⁴ may form a covalent bond or a coordinate bond with at least one selected from R₁ₐ, R^{1b}, or R³, and R^{4A} and R^{4B} each independently represent a substituent. R^{4A} and R^{4B} may be bonded to each other to form a ring. The details of Formula (PP) can be found in paragraphs “0017” to “0047” of JP2009-263614A, paragraphs “0011” to “0036” of JP2011-068731A, and paragraphs “0010” to “0024” of WO2015/166873A, the contents of which are incorporated herein by reference.

In Formula (PP), R^{1a} and R^{1b} each independently represent preferably an aryl group or a heteroaryl group, and more preferably an aryl group. In addition, the alkyl group, the aryl group, and the heteroaryl group represented by R^{1a} and R^{1b} may have a substituent or may be unsubstituted. Examples of the substituent include substituents described in paragraphs “0020” to “0022” of 2009-263614A and the following substituent T.

(Substituent T)

The substituent T includes an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably having an acyl group 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), a heteroarylsulfonyl group (preferably having t to 30 carbon atoms), an alkylsulfinyl group (preferably having 1 to 30 carbon atoms), an arylsulfinyl group (preferably having 6 to 30 carbon atoms), a heteroarylsulfinyl group (preferably having 1 to 30 carbon atoms), a ureido group (preferably having 1 to 30 carbon atoms), a hydroxy group, a carboxyl group, a sulfo group, a phosphate group, a carboxylic acid amide group (preferably a group represented by —NHCOR^{A1}, R^{A1} representing a hydrocarbon group or a heterocyclic group in which the hydrocarbon group and the heterocyclic group may further have a substituent, preferably a halogen atom and more preferably a fluorine atom), a sulfonic acid amide group (preferably a group represented by —NHSO₂R^{A2}, R^{A2} representing a hydrocarbon group or a heterocyclic group in which the hydrocarbon group and the heterocyclic group may further have a substituent, preferably a halogen atom and more preferably a fluorine atom), an imide acid group (preferably a group represented by —SO₂NHSO₂R^{A3}, —CONHSO₂R^{A4}, —CONHCOR^{A5}, or —SO₂NHCOR^{A6}, R^{A3} to R^{A6} each independently representing a hydrocarbon group or a heterocyclic group in which the hydrocarbon group and the heterocyclic group may further have a substituent), a mercapto group, a halogen atom, a cyano group, an alkylsulfino group, an arylsulfino group, a hydrazino group, an imino group, and a heteroaryl group (preferably having 1 to 30 carbon atoms).

In a case where the above-described groups can be further substituted, the groups may further have a substituent. Examples of the substituent include the groups described regarding the substituent T.

Specific examples of the group represented by R^{1a} and R^{1b} include an aryl group which has an alkoxy group as a substituent, an aryl group which has a hydroxyl group as a substituent, and an aryl group which has an acyloxy group as a substituent.

In Formula (PP), R² and R³ each independently represent a hydrogen atom or a substituent. Examples of the substituent include the above-described substituent T. It is preferable that at least one of R² or R³ represents an electron-withdrawing group. A substituent having a positive Hammett's substituent constant σ value (sigma value) acts as an electron-withdrawing group. Here, the substituent constant obtained by Hammett's rule includes a σp value and a am value. The values can be found in many common books. In the present invention, a substituent having the Hammett's substituent constant σ value of 0.2 or more can be exemplified as the electron-withdrawing group. σ value is preferably 0.25 or more, more preferably 0.3 or more, and still more preferably 0.35 or more. The upper limit is not particularly limited, but preferably 0.80 or less. Specific examples of the electron-withdrawing group include a cyano group (σp value=0.66), a carboxyl group (—COOH: σp value=0.45), an alkoxycarbonyl group (for example, —COOMe: σp value=0.45), an aryloxycarbonyl group (for example, —COOPh: σp value=0.44), a carbamoyl group (for example, —CONH₂: σp value=0.36), an alkylcarbonyl group (for example, —COMe: σp value=0.50), an arylcarbonyl group (for example, —COPh: σp value=0.43), an alkylsulfonyl group (for example, —SO₂Me: σp value=0.72), and an arylsulfonyl group (for example, —SO₂Ph: σp value=0.68). Among these, a cyano group is preferable. Here, Me represents a methyl group, and Ph represents a phenyl group. For example, the Hammett's substituent constant σ value can be found in the description of paragraphs “0017” and “0018” of JP2011-068731A, the content of which is incorporated herein by reference.

In Formula (PP), it is preferable that R² represents an electron-withdrawing group (preferably a cyano group) and R³ represents a heteroaryl group. It is preferable that the heteroaryl group is a 5-membered or 6-membered ring. In addition, the heteroaryl group is preferably a monocyclic or a fused ring, more preferably a monocycle or a fused ring composed of 2 to 8 rings, and still more preferably a monocycle or a fused ring composed of 2 to 4 rings. The number of heteroatoms constituting the heteroaryl group is preferably 1 to 3 and more preferably 1 or 2. Examples of the heteroatom include a nitrogen atom, an oxygen atom, and a sulfur atom. It is preferable that the heteroaryl group has one or more nitrogen atoms. Two R²'s in Formula (PP) may be the same as or different from each other. In addition, two R³'s in Formula (PP) may be the same as or different from each other.

In Formula (PP), R⁴ represents preferably a hydrogen atom, an alkyl group, an aryl group, a heteroaryl group, or a group represented by —BR^{4A}R^{4B}, more preferably a hydrogen atom, an alkyl group, an aryl group, or a group represented by —BR^{4A}R^{4B}, and still more preferably a group represented by —BR^{4A}R^{4B}. As the substituent represented by R^{4A} and R^{1B}, a halogen atom, an alkyl group, an alkoxy group, an aryl group, or a heteroaryl group is preferable, an alkyl group, an aryl group, or a heteroaryl group is more preferable, and an aryl group is still more preferable. Each of the groups may further have a substituent. Two R⁴'s in Formula (PP) may be the same as or different from each other. R^{4A} and R^{4B} may be bonded to each other to form a ring.

Specific examples of the compound represented by Formula (PP) include the following compounds. In the following structural formulae, Me represents a methyl group, and Ph represents a phenyl group. In addition, Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

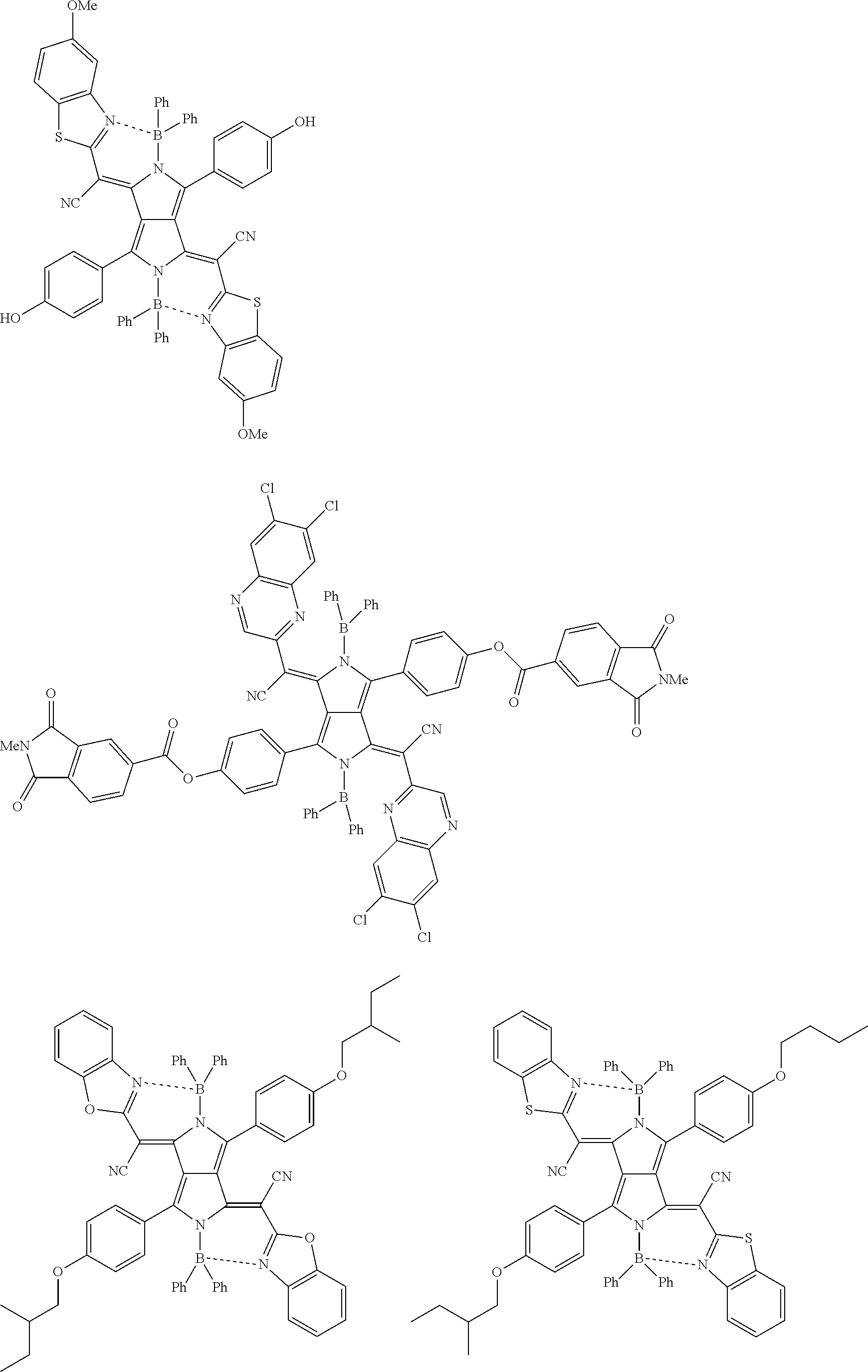

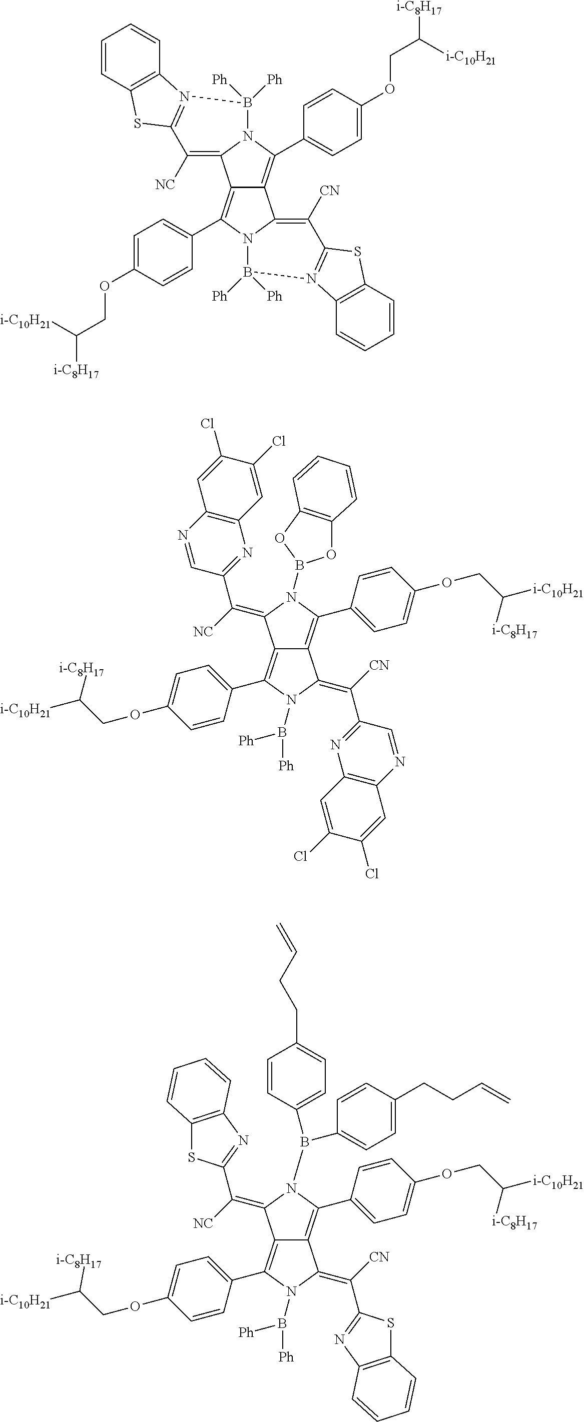

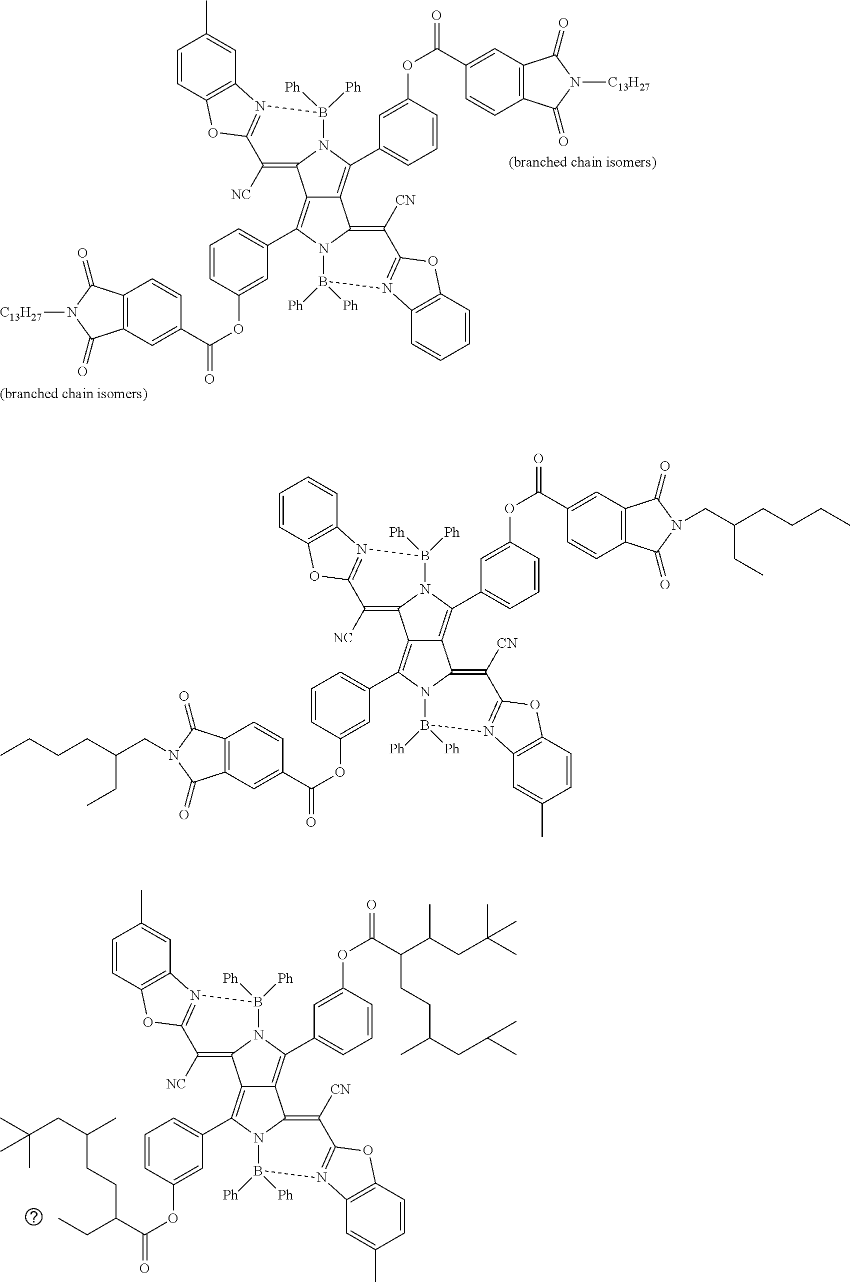

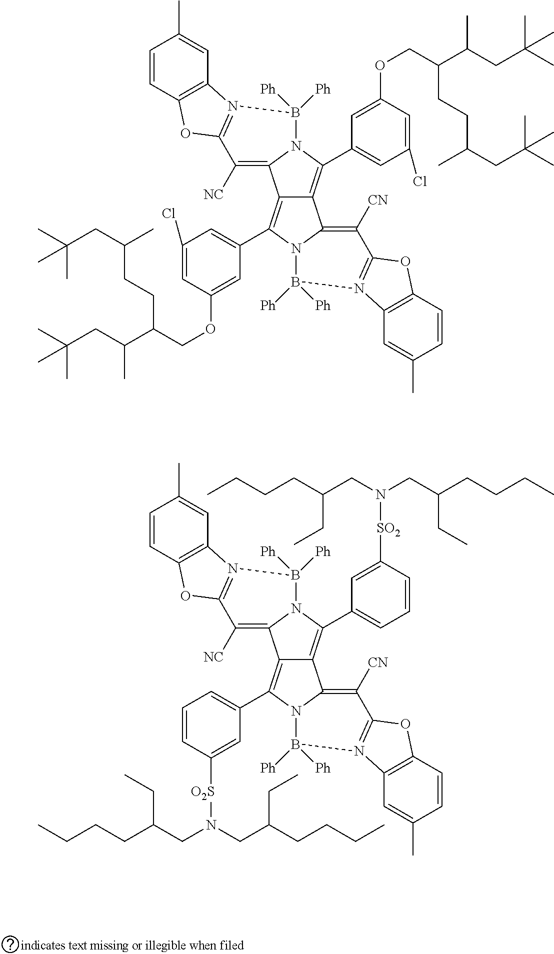

As the squarylium compound, a compound represented by the following Formula (SQ) is preferable.

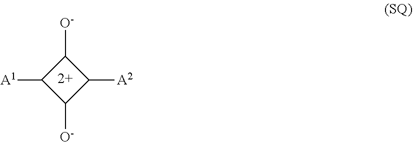

In Formula (SQ), A¹ and A² each independently represent an aryl group, a heteroaryl group, or a group represented by Formula (A-1).

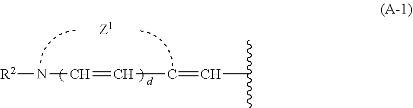

In Formula (A-1), Z¹ represents a non-metal atomic group for forming a nitrogen-containing heterocycle, R² represents an alkyl group, an alkenyl group, or an aralkyl group, d represents 0 or 1, and a wave line represents a direct bond. The details of Formula (SQ) can be found in paragraphs “0020” to “0049” of JP2011-208101A, paragraphs “0043” to “0062” of JP6065169B, and paragraphs “0024” to “0040” of WO2016/181987A, the contents of which are incorporated herein by reference.

As shown below, cations in Formula (SQ) are present without being localized.

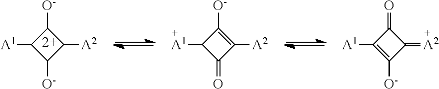

As the squarylium compound, a compound represented by the following Formula (SQ-1) is preferable.

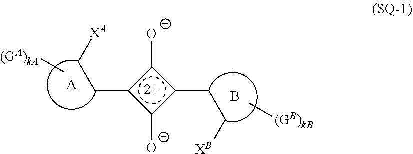

A Ring A and a ring B each independently represent an aromatic ring, X^{A} and X⁸ each independently represent a substituent, G^{A} and G^{B} each independently represent a substituent, kA represents an integer of 0 to n_{A}, kB represents an integer of 0 to n_{B}, n_{A} and nᵤ represent an integer representing the maximum numbers of G^{A}'s and G^{B}'s which may be substituted in the ring A and the ring B, respectively, X^{A} and G^{A}, X^{B} and G^{B}, or X^{A} and X^{B} may be bonded to each other to form a ring, and in a case where a plurality of G^{A}'s and a plurality of G^{B}'s are present, G^{A}'s and G^{B}'s may be bonded to each other to form ring structures, respectively.

Examples of a substituent represented by G^{A} and G^{B} include the substituent T described in Formula (PP).

As a substituent represented by X^{A} and X^{B}, a group having an active hydrogen is preferable, —OH, —SH, —COOH, —SO₃H, —NR^{X1}R^{X2}, —NHCOR^{X1}, —CONR^{X1}R^{X2}, —NHCONR^{X1}R^{X2}, —NHCOOR^{X1}, —NHSO₂R^{X1}, —B(OH)₂, and —PO(OH)₂ is more preferable, and —OH, —SH, and —N^{X1}R^{X2} is still more preferable. R^{X1} and R^{X2} each independently represent a hydrogen atom or a substituent. Examples of the substituent represented by X^{A} and X^{B} include an alkyl group, an aryl group, and a heteroaryl group. Among these, an alkyl group is preferable.

The ring A and the ring B each independently represent an aromatic ring. The aromatic ring may be a monocyclic or a fused ring. Specific examples of the aromatic ring include a benzene ring, a naphthalene ring, a pentalene ring, an indene ring, an azulene ring, a heptalene ring, an indacene ring, a perylene ring, a pentacene ring, an acenaphthene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolidine ring, a quinoline ring, a phthalazine ring, a naphthyridine ring, a quinoxaline ring, a quinoxaline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring. Among these, a benzene ring or a naphthalene ring is preferable. The aromatic ring may be unsubstituted or may have a substituent. Examples of the substituent include the substituent T described in Formula (PP).

X^{A} and G^{A}, X^{B} and G^{B}, or X^{A} and X^{B} may be bonded to each other to form a ring, and in a case where a plurality of G^{A}'s and G^{B}'s are present, G^{A}'s and G^{B}'s may be bonded to each other to form rings, respectively. It is preferable that the ring is a 5-membered or 6-membered ring. The ring may be a monocyclic or a fused ring. In a case where X^{A} and G^{A}, X^{B} and G^{B}, X^{A} and X^{B}, G^{A}'s, and G^{B}'s are bonded to each other to form a ring, these may be directly bonded to each other form a ring or may be bonded to each other through an alkylene group, —CO—, —O—, —NH—, —BR—, or a divalent linking group including a combination thereof to form a ring. R represents a hydrogen atom or a substituent. Examples of the substituent include the substituent T described in Formula (PP). Among these, an alkyl group or an aryl group is preferable.

kA represents an integer of 0 to n_{A}, kB represents an integer of 0 to n_{B}, n_{A} represents the largest integer that can be substituted for the ring A, and n_{B} represents the largest integer that can be substituted for the ring B. kA and kB each independently represent preferably 0 to 4, more preferably 0 to 2, and still more preferably 0 or 1.

As the squarylium compound, a compound represented by the following Formula (SQ-10), Formula (SQ-11), or Formula (SQ-12) is preferable.

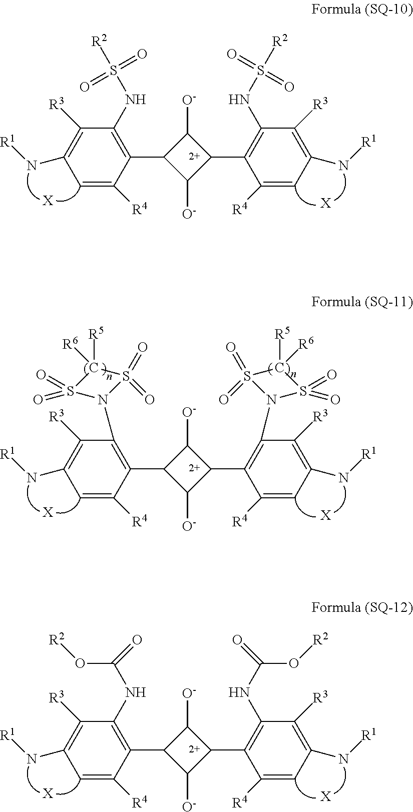

In the Formulae (SQ-10) to (SQ-12), X's each independently represent a divalent organic group represented by Formula (S1) or Formula (S2) in which one or more hydrogen atoms may be substituted with a halogen atom or an alkyl group or an alkoxy group having 1 to 12 carbon atoms.

—(CH₂)ₙ₁— (S1)

In Formula (S1), n1 represents 2 or 3.

—(CH₂)ₙ₂—O—(CH₂)ₙ₃— (S2)

In Formula (S2), n2 and n3 each independently represent an integer of 0 to 2, and n2+n3 is 1 or 2.

R¹ and R² each independently represent an alkyl group or an aryl group. The alkyl group and the aryl group may have a substituent or may be unsubstituted. Examples of the substituent include the substituent T described in Formula (PP).

R³ to R⁶ each independently represent a hydrogen atom, a halogen atom, an alkyl group, or an alkoxy group.

n is 2 or 3.

Specific examples of the squarylium compound include compounds having the following structures. In addition, examples of the squarylium compound include a compound described in paragraphs “0044” to “0049” of JP2011-208101A, a compound described in paragraphs “0060” and “0061” of JP6065169B, a compound described in paragraph “0040” of WO2016/181987A, a compound described in WO2013/133099A, a compound described in WO2014/088063A, a compound described in JP2014-126642A, a compound described in JP2016-146619A, a compound described in JP2015-176046A, a compound described in JP2017-025311A, a compound described in WO2016/154782A, a compound described in JP5884953B, a compound described in JP6036689B, a compound described in JP5810604B, and a compound described in JP2017-068120A, the contents of which are incorporated herein by reference.

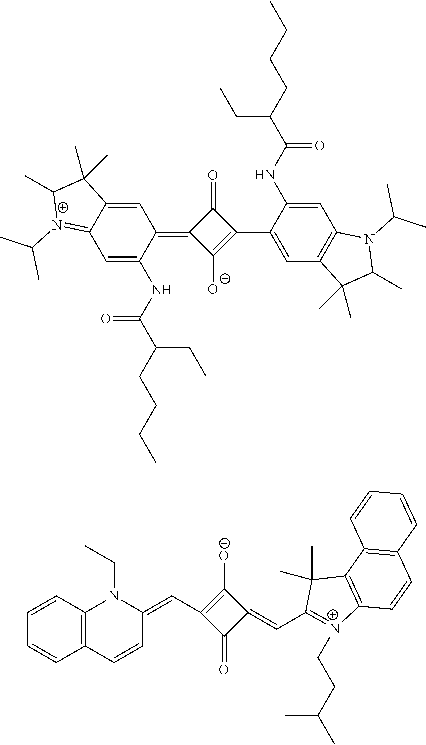 [SMILES: CCCCC(CC)C(=O)Nc1cc2c(cc1C1=C([O-])/C(=c3/cc4c(cc3NC(=O)C(CC)CCCC)=[N+](C(C)C)C(C)C4(C)C)C1=O)C(C)(C)C(C)N2C(C)C ; CCN1/C(=C/C2=C(O)C(=C\C3=[N+](CCC(C)C)c4ccc5ccccc5c4C3(C)C)/C2=O)C=Cc2ccccc21]

As the cyanine compound, a compound represented by Formula (C) is preferable. Formula (C)

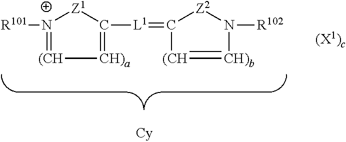

In the formula, Z¹ and Z² each independently represent a non-metal atomic group for forming a 5- or 6-membered nitrogen-containing heterocycle which may be fused, R¹⁰¹ and R¹⁰² each independently represent an alkyl group, an alkenyl group, an alkynyl group, an aralkyl group, or an aryl group, L¹ represents a methine chain including an odd number of methine groups, and a and b each independently represent 0 or 1, and in a case where a represents 0, a carbon atom and a nitrogen atom are bonded through a double bond, in a case where b represents 0, a carbon atom and a nitrogen atom are bonded through a single bond. In a case where a portion represented by Cy in the formula is a cation site, X′ represents an anion and c represents the number of X¹'s for balancing charge, in a case where a site represented by Cy in the formula is an anion site, X′ represents a cation and c represents the number of X¹'s for balancing charge, and in a case where charge of a site represented by Cy in the formula is neutralized in a molecule, c represents 0.

Specific examples of the cyanine compound include the following compounds. In addition, examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, a compound described in JP2008-088426A, and a compound described in JP2017-031394A, the contents of which are incorporated herein by reference.

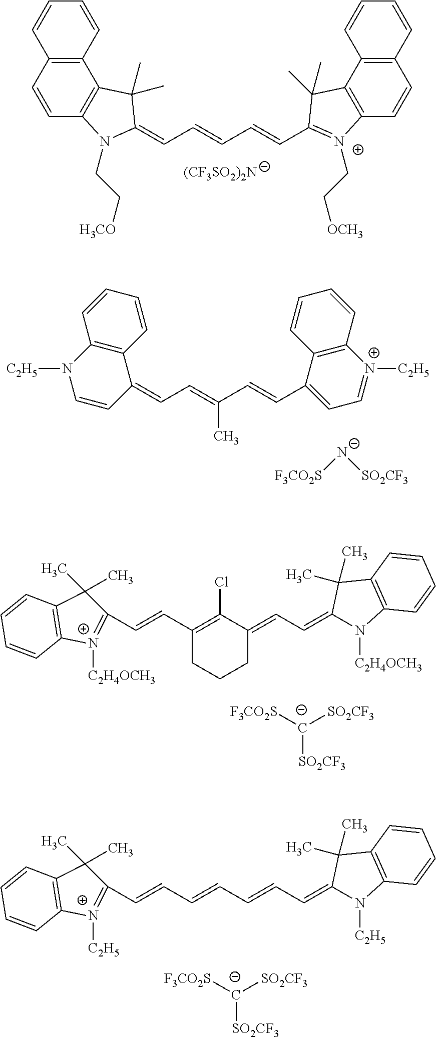

In the present invention, as the near infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LD1 (manufactured by Fujifilm Corporation); NK-3027 and NK-5060 (manufactured by Hayashibara Co., Ltd.); and YKR-3070 (manufactured by Mitsui Chemicals, Inc.).

In a case where the curable composition according to the embodiment of the present invention includes a near infrared absorbing colorant, the content of the near infrared absorbing colorant is preferably 1 to 50 mass % with respect to the total solid content of the curable composition. The upper limit is preferably 40 mass % or lower and more preferably 30 mass % or lower. The lower limit is preferably 3 mass % or higher and more preferably 5 mass % or higher.

In addition, the content of the near infrared absorbing colorant is preferably 10 to 70 parts by mass with respect to 100 parts by mass of the total mass of the chromatic colorant and the organic black colorant. The upper limit is preferably 60 parts by mass or less and more preferably 50 parts by mass or less. The lower limit is preferably 20 parts by mass or more and more preferably 30 parts by mass or more.

In addition, the content of the near infrared absorbing colorant is preferably 5 to 60 mass % with respect to the total mass of the coloring material. The upper limit is preferably 50 mass % or lower, and more preferably 40 mass % or lower. The lower limit is preferably 10 mass % or higher and more preferably 15 mass % or higher. As the near infrared absorbing colorant, one kind may be used alone, or two or more kinds may be used in combination. In a case where two or more kinds of near infrared absorbing colorants are used in combination, it is preferable that the total content of the two or more kinds of near infrared absorbing colorants is in the above-described range.

<<Curable Compound>>

The curable composition according to the embodiment of the present invention includes a curable compound. Examples of the curable compound include a polymerizable compound and a resin. The resin may be a non-polymerizable resin (resin not having a polymerizable group) or a polymerizable resin (resin having a polymerizable group). Examples of the polymerizable group include a group having an ethylenically unsaturated bond, an epoxy group, a methylol group, and an alkoxymethyl group. Examples of the group having an ethylenically unsaturated bond include a vinyl group, a (meth)allyl group, and a (meth)acryloyl group.

In the present invention, it is preferable that a compound including at least a resin is used as the curable compound, it is more preferable that a resin and a monomer type polymerizable compound are used as the curable compound, and it is still more preferable that a resin and a monomer type polymerizable compound which has a group having an ethylenically unsaturated bond are used as the curable compound.

In the curable composition according to the embodiment of the present invention, the content of the curable compound is preferably 0.1 to 50 mass % with respect to the total solid content of the curable composition. The lower limit is, for example, preferably 0.5 mass % or higher and more preferably 1 mass % or higher. The upper limit is, for example, preferably 40 mass % or lower and more preferably 30 mass % or lower. As the curable compound, one kind may be used alone, or two or more kinds may be used. In a case where two or more kinds of curable compounds are used in combination, it is preferable that the total content of the two or more kinds of curable compounds is in the above-described range.

(Polymerizable Compound)

Examples of the polymerizable compound include a compound which has a group having an ethylenically unsaturated bond, a compound having an epoxy group, a compound having a methylol group, and a compound having an alkoxymethyl group. The polymerizable compound may be a monomer or a resin. The monomer type polymerizable compound which has a group having an ethylenically unsaturated bond can be preferably used as a radically polymerizable compound. In addition, the compound having an epoxy group, the compound having a methylol group, and the compound having an alkoxymethyl group can be preferably used as a cationically polymerizable compound.

The molecular weight of the monomer type polymerizable compound is preferably lower than 2000, more preferably 100 or higher and lower than 2000, and still more preferably 200 or higher and lower than 2000. The upper limit is, for example, preferably 1500 or lower. The weight-average molecular weight (Mw) of the resin type polymerizable compound is preferably 2,000 to 2,000,000. The upper limit is preferably 1,000,000 or lower and more preferably 500,000 or lower. The lower limit is preferably 3,000 or higher and more preferably 5,000 or higher.

Examples of the resin type polymerizable compound include an epoxy resin and a resin which includes a repeating unit having a polymerizable group. Examples of the repeating unit having a polymerizable group include the Formulae (A2-1) to (A2-4).

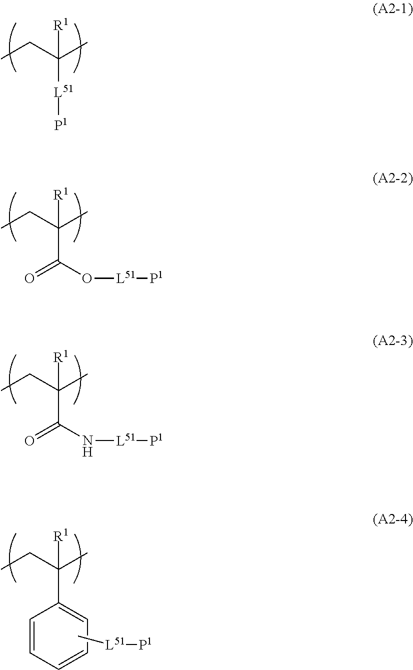

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof. The number of carbon atoms in the alkylene group is preferably 1 to 30, more preferably 1 to 15, and still more preferably 1 to 10. The alkylene group may have a substituent, but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

P¹ represents a polymerizable group. Examples of the polymerizable group include a group having an ethylenically unsaturated bond, an epoxy group, a methylol group, and an alkoxymethyl group.

As the compound which has a group having an ethylenically unsaturated bond, a (meth)acrylate compound having 3 to 15 functional groups is preferable and a (meth)acrylate compound having 3 to 6 functional groups is more preferable. Examples of the compound which has a group having an ethylenically unsaturated bond can be found in paragraphs “0033” and “0034” of JP2013-253224A, the content of which is incorporated herein by reference. As the compound which has a group having an ethylenically unsaturated bond, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a structure in which the (meth)acryloyl group is bonded through an ethylene glycol residue and/or a propylene glycol residue is preferable. In addition, oligomers of the above-described compounds can also be used. In addition, the details of the compound including a group having an ethylenically unsaturated bond can be found in paragraphs “0034” to “0038” of JP2013-253224A, the content of which is incorporated herein by reference. Examples of the compound having an ethylenically unsaturated bond include a polymerizable monomer in paragraph “0477” of JP2012-208494A (corresponding to paragraph “0585” of US2012/0235099A), the contents of which are incorporated herein by reference. In addition, diglycerin ethylene oxide (EO)-modified (meth)acrylate (as a commercially available product, M-460 manufactured by Toagosei Co., Ltd.), pentaerythritol tetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) is also preferable. Oligomers of the above-described compounds can also be used. For example, RP-1040 (manufactured by Nippon Kayaku Co., Ltd.) is used. In addition, as the radically polymerizable compound, ARONIX M-350 or TO-2349 (manufactured by Toagosei Co., Ltd.) can be used.

The compound which has a group having an ethylenically unsaturated bond may further have an acid group such as a carboxyl group, a sulfo group, or a phosphate group. Examples of a commercially available product include ARONIX series (for example, M-305, M-510, or M-520, manufactured by Toagosei Co., Ltd.).

In addition, a compound having a caprolactone structure is also preferable as the compound which has a group having an ethylenically unsaturated bond. Examples of the compound having a caprolactone structure can be found in paragraphs “0042” to “0045” of JP2013-253224A, the content of which is incorporated herein by reference. As the compound having a caprolactone structure, for example, KAYARAD DPCA series (manufactured by Nippon Kayaku Co., Ltd.) are commercially available, and examples thereof include DPCA-20, DPCA-30, DPCA-60, and DPCA-120.

As the compound which has a group having an ethylenically unsaturated bond, a compound which has a group having an ethylenically unsaturated bond and an alkyleneoxy group can also be used. As the compound which has a group having an ethylenically unsaturated bond and an alkyleneoxy group, a compound which has a group having an ethylenically unsaturated bond, an ethyleneoxy group, and/or a propyleneoxy group is preferable, a compound which has a group having an ethylenically unsaturated bond and an ethyleneoxy group is more preferable, and a trifunctional to hexafunctional (meth)acrylate compound having 4 to 20 ethyleneoxy groups is still more preferable. Examples of a commercially available product of the compound which has a group having an ethylenically unsaturated bond and an alkyleneoxy group include SR-494 (manufactured by Sartomer) which is a tetrafunctional (meth)acrylate having four ethyleneoxy groups, and KAYARAD TPA-330 (manufactured by Nippon Kayaku Co., Ltd.) which is a trifunctional (meth)acrylate having three isobutyleneoxy groups.

As the compound which has a group having an ethylenically unsaturated bond, a urethane acrylate described in JP1973-041708B (JP-S48-041708B), JP1976-037193A (JP-S51-037193A), JP1990-032293B (JP-H02-032293B), or JP1990-016765B (JP-H02-016765B), or a urethane compound having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) is also preferable. In addition, an addition-polymerizable compound having an amino structure or a sulfide structure in the molecules described in JP1988-277653A (JP-S63-277653A), JP1988-260909A (JP-S63-260909A), or JP1989-105238A (JP-H01-105238A) can be used. Examples of a commercially available product of the addition-polymerizable compound include UA-7200 (manufactured by Shin-Nakamura Chemical Co., Ltd.), DPHA-40H (manufactured by Nippon Kayak) Co., Ltd.), and UA-306H, UA-306T, UA-306I, AH-600, T-600 and AI-600 (manufactured by Kyoeisha Chemical Co., Ltd.).

In addition, as the compound which has a group having an ethylenically unsaturated bond, a compound described in JP2017-048367A, JP6057891B, or JP6031807B can also be used.

In addition, as the compound which has a group having an ethylenically unsaturated bond, for example, 8UH-1006 or 8UH-1012 (manufactured by Taisei Fine Chemical Co., Ltd.) or LIGHT ACRYLATE POB-A0 (manufactured by Kyoeisha Chemical Co., Ltd.) is also preferably used.

In a case where the curable composition according to the embodiment of the present invention includes the compound which has a group having an ethylenically unsaturated bond, the content of the compound which has a group having an ethylenically unsaturated bond is preferably 0.1 to 50 mass % with respect to the total solid content of the curable composition. The lower limit is, for example, preferably 0.5 mass % or higher and more preferably 1 mass % or higher. The upper limit is, for example, preferably 40 mass % or lower and more preferably 30 mass % or lower.

In addition, the content of the monomer type compound which has a group having an ethylenically unsaturated bond is preferably 0.1 to 50 mass % with respect to the total solid content of the curable composition. The lower limit is, for example, preferably 0.5 mass % or higher and more preferably 1 mass % or higher. The upper limit is, for example, preferably 40 mass % or tower and more preferably 30 mass % or lower.

Examples of the compound (hereinafter, also referred to as an epoxy compound) having an epoxy group include a monofunctional or polyfunctional glycidyl ether compound, and a polyfunctional aliphatic glycidyl ether compound. In addition, as the epoxy compound, a compound having an alicyclic epoxy group can also be used.

Examples of the epoxy compound include a compound having one or more epoxy groups in one molecule. It is preferable that the epoxy compound is a compound having 1 to 100 epoxy groups in one molecule. The upper limit of the number of epoxy groups is, for example, 10 or less or 5 or less. The lower limit of the number of epoxy groups is preferably 2 or more.

The epoxy compound may be a low molecular weight compound (for example, molecular weight: lower than 1000) or a high molecular weight compound (macromolecule; for example, molecular weight: 1000 or higher, and in the case of a polymer, weight-average molecular weight: 1000 or higher). The weight-average molecular weight of the epoxy compound is preferably 2000 to 100000. The upper limit of the weight-average molecular weight is preferably 10000 or lower, more preferably 5000 or lower, and still more preferably 3000 or lower.

Examples of a commercially available product of the epoxy compound include EHPE 3150 (manufactured by Daicel Corporation), EPICLON N-695 (manufactured by D1C Corporation), ADEKA GLYCILOL ED-505 (manufactured by ADEKA Corporation, an epoxy group-containing monomer), and MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer). In addition, as the epoxy compound, compounds described in paragraphs “0034” to “0036” of JP2013-011869A, paragraphs “0147” to “0156” of JP2014-043556A, and paragraphs “0085” to “0092” of JP2014-089408A can also be used. The contents of which are incorporated herein by reference.

In a case where the curable composition according to the embodiment of the present invention includes the epoxy compound, the content of the epoxy compound is preferably 0.1 to 50 mass % with respect to the total solid content of the curable composition. The lower limit is, for example, preferably 0.5 mass % or higher and more preferably 1 mass % or higher. The upper limit is, for example, preferably 40 mass % or lower and more preferably 30 mass % or lower.

Examples of the compound having a methylol group (hereinafter, also referred to as a methylol compound) include a compound in which a methylol group is bonded to a nitrogen atom or a carbon atom which forms an aromatic ring. In addition, examples of the compound having an alkoxymethyl group (hereinafter, also referred to as an alkoxymethyl compound) include a compound in which an alkoxymethyl group is bonded to a nitrogen atom or a carbon atom which forms an aromatic ring. As the compound in which an alkoxymethyl group or a methylol group is bonded to a nitrogen atom, for example, alkoxy methylated melamine, methylolated melamine, alkoxy methylated benzoguanamine, methylolated benzoguanamine, alkoxy methylated glycoluril, methylolated glycoluril, alkoxy methylated urea, or methylolated urea is preferable. In addition, the details of the compound can be found in paragraphs “0134” to “0147” of JP2004-295116A or paragraphs “0095” to “0126” of JP2014-089408A, the contents of which are incorporated herein by reference.

In a case where the curable composition according to the embodiment of the present invention includes a methylol compound, the content of the methylol compound is preferably 0.1 to 50 mass % with respect to the total solid content of the curable composition. The lower limit is, for example, preferably 0.5 mass % or higher and more preferably 1 mass % or higher. The upper limit is, for example, preferably 40 mass % or lower and more preferably 30 mass % or lower.

In a case where the curable composition according to the embodiment of the present invention includes an alkoxymethyl compound, the content of the alkoxymethyl compound is preferably 0.1 to 50 mass % with respect to the total solid content of the curable composition. The lower limit is, for example, preferably 0.5 mass % or higher and more preferably 1 mass % or higher. The upper limit is, for example, preferably 40 mass % or lower and more preferably 30 mass % or lower.

(Resin)

The curable composition according to the embodiment of the present invention can include a resin as the curable compound. It is preferable that the curable compound includes at least a resin. The resin can also be used as a dispersant. The resin which is used to disperse the pigments and the like will also be referred to as a dispersant. However, the above-described uses of the resin are merely exemplary, and the resin can be used for purposes other than the uses. The resin having a polymerizable group also corresponds to the polymerizable compound.

The weight-average molecular weight (Mw) of the resin is preferably 2,000 to 2,000,000. The upper limit is preferably 1,000,000 or lower and more preferably 500,000 or lower. The lower limit is preferably 3,000 or higher and more preferably 5,000 or higher.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Examples of the epoxy resin include the polymer type compounds among the compounds described above as the examples of the epoxy compound in column of the polymerizable compound. Examples of a commercially available product of the cyclic olefin resin include ARTON F4520 (manufactured by JSR Corporation). In addition, a resin described in Examples of WO2016/088645A, a resin described in JP2017-057265A, a resin described in JP2017-032685A, a resin described in JP2017-075248A, or a resin described in JP2017-066240A can also be used, the contents of which are incorporated herein by reference. In addition, a resin having a fluorene skeleton can also be preferably used. Examples of the resin having a fluorene skeleton include a resin having the following structure. In the following structural formula, A represents a residue of a carboxylic acid dianhydride selected from pyromellitic acid dianhydride, benzophenone tetracarboxylic acid dianhydride, biphenyl tetracarboxylic acid dianhydride, or diphenyl ether tetracarboxylic acid dianhydride, and M represents a phenyl group or a benzyl group. The resin having a fluorene skeleton can be found in the description of US2017/0102610A, the content of which is incorporated herein by reference.

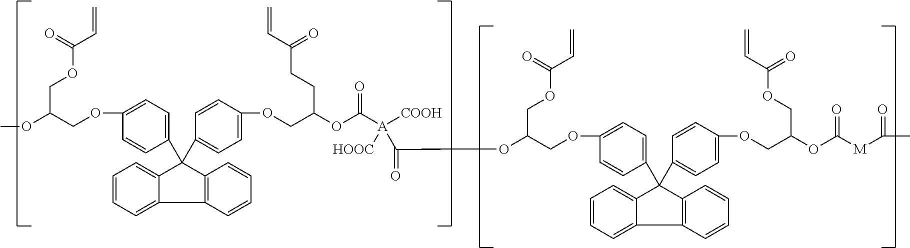

The resin used in the present invention may have an acid group. Examples of the acid group include a carboxyl group, a phosphate group, a sulfo group, and a phenolic hydroxy group. Among these, a carboxyl group is preferable. Among these acid groups, one kind may be used alone, or two or more kinds may be used in combination. The resin having an acid group can also be used as an alkali-soluble resin.

As the resin having an acid group, a polymer having a carboxyl group in a side chain is preferable. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the another monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of the another monomer include a N-position-substituted maleimide monomer described in JP1998-300922A (JP-H10-300922A) such as N-phenylmaleimide or N-cyclohexylmaleimide. Among these monomers which are copolymerizable with the (meth)acrylic acid, one kind may be used alone, or two or more kinds may be used in combination.

The resin having an acid group may further contain a repeating unit having a polymerizable group. In a case where the resin having an acid group further contains the repeating unit having a polymerizable group, the content of the repeating unit having a polymerizable group is preferably 10 to 90 mol %, more preferably 20 to 90 mol %, and still more preferably 20 to 85 mol % with respect to all the repeating units. In addition, the content of the repeating unit having an acid group is preferably 1 to 50 mol %, more preferably 5 to 40 mol %, and still more preferably 5 to 30 mol % with respect to all the repeating units.

As the resin having an acid group, a copolymer including benzyl (meth)acrylate and (meth)acrylic acid; a copolymer including benzyl (meth)acrylate, (meth)acrylic acid, and 2-hydroxyethyl (meth)acrylate; or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer which is obtained by polymerizing monomer components including a compound represented by the Formula (ED1) and/or a compound represented by the Formula (ED2) (hereinafter, these compounds will also be referred to as an “ether dimer”) is also preferable.

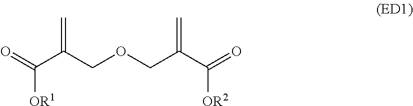

In Formula (ED1), R¹ and R² each independently represent a hydrogen atom or a hydrocarbon group having 1 to 25 carbon atoms which may have a substituent.

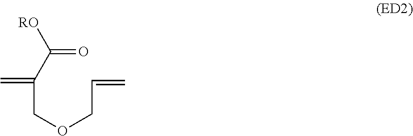

In Formula (ED2), R represents a hydrogen atom or an organic group having 1 to 30 carbon atoms. Specific examples of compounds represented by Formula (ED2) can be found in the description of JP2010-168539A.

Specific examples of the ether dimer can be found in paragraph “0317” of JP2013-029760A, the content of which is incorporated herein by reference. Among these ether dimers, one kind may be used alone, or two or more kinds may be used in combination.

The resin having an acid group may include a repeating unit which is derived from a compound represented by the following Formula (X).

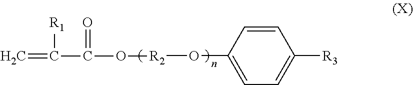

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

An acid value of the resin having an acid group is preferably 30 to 200 mgKOH/g. The lower limit is preferably 50 mgKOH/g or higher and more preferably 70 mgKOH/g or higher. The upper limit is preferably 150 mgKOH/g or lower and more preferably 120 mgKOH/g or lower.

Examples of the resin having an acid group include resins having the following structures. In the following structural formulae, Me represents a methyl group.

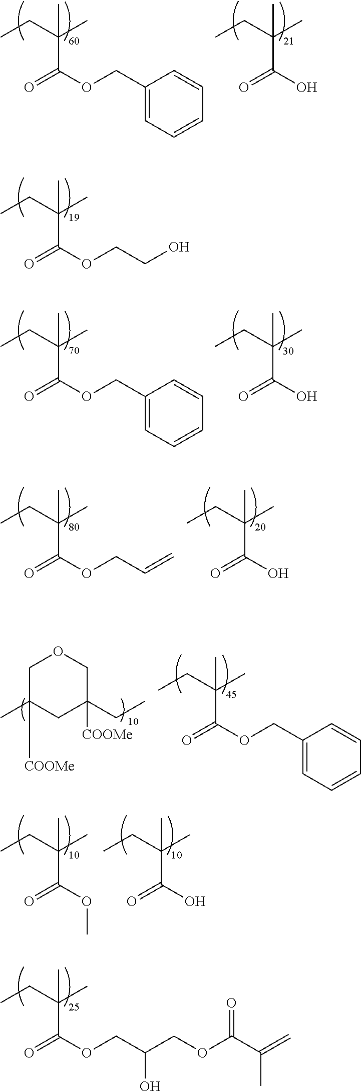

The curable composition according to the embodiment of the present invention may include a resin as a dispersant. Examples of the dispersant include an acidic dispersant (acidic resin) and a basic dispersant (basic resin). Here, the acidic dispersant (acidic resin) refers to a resin in which the amount of an acid group is more than the amount of a basic group. In a case where the total content of an acid group and a basic group in the acidic dispersant (acidic resin) is represented by 100 mol %, the amount of the acid group in the acidic resin is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group is more than the amount of an acid group. In a case where the total content of an acid group and a basic group in the basic dispersant (basic resin) is represented by 100 mol %, the amount of the basic group in the basic resin is preferably higher than 50 mol %. The basic group in the basic dispersant is preferably an amino group.

It is preferable that the resin used as the dispersant further includes a repeating unit having an acid group. By the resin, which is used as a dispersant, including the repeating unit having an acid group, in a case where a pattern is formed using a photolithography method, the amount of residues formed in an underlayer of a pixel can be reduced.

It is preferable that the resin used as a dispersant is a graft copolymer. Since the graft copolymer has affinity to the solvent due to the graft chain, the pigment dispersibility and the dispersion stability over time are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference

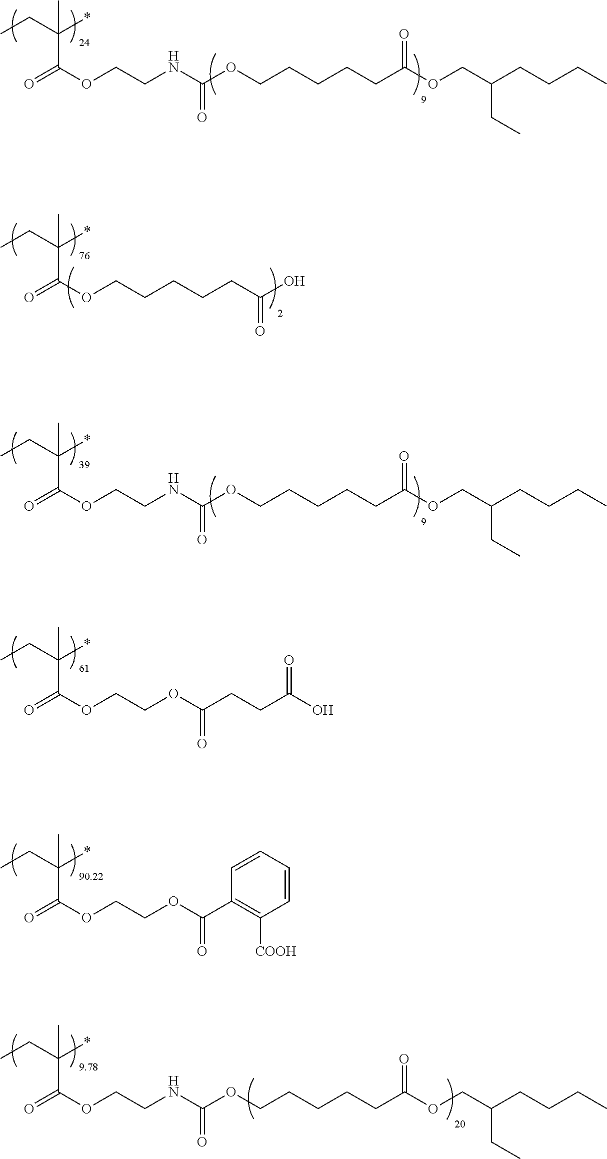

In addition, in the present invention, as the resin (dispersant), an oligoimine-based dispersant having a nitrogen atom in at least either a main chain or a side chain is also preferably used. As the oligoimine-based dispersant, a resin, which includes a structural unit having a partial structure X with a functional group (pKa: 14 or lower) and a side chain including a side chain Y having 40 to 10,000 atoms and has a basic nitrogen atom in at least either a main chain or a side chain, is preferable. The basic nitrogen atom is not particularly limited as long as it is a nitrogen atom exhibiting basicity. The oligoimine-based dispersant can be found in the description of paragraphs “0102” to “0166” of JP2012-255128A, the content of which is incorporated herein by reference. As the oligoimine dispersant, a resin having the following structure or a resin described in paragraphs “0168” to “0174” of JP2012-255128A can be used.

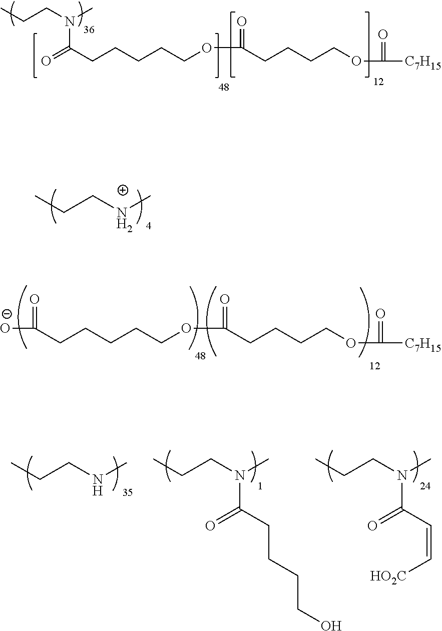

The dispersant is available as a commercially available product, and specific examples thereof include BYK2000 (manufactured by BYK Chemie Japan). In addition, a pigment dispersant described in paragraphs “0041” to “0130” of JP2014-130338A can also be used, the content of which is incorporated herein by reference. In addition, the resin having an acid group or the like can also be used as a dispersant.

In a case where the curable composition according to the embodiment of the present invention includes the resin, the content of the resin is preferably 0.1 to 50 mass % with respect to the total solid content of the curable composition. The lower limit is preferably 1 mass % or higher, more preferably 3 mass % or higher, and still more preferably 5 mass % or higher. The upper limit is, for example, preferably 40 mass % or lower and more preferably 30 mass % or lower.

In addition, the content of the resin having an acid group is preferably 0.1 to 50 mass % with respect to the total solid content of the curable composition according to the embodiment of the present invention. The lower limit is preferably 1 mass % or higher, more preferably 3 mass % or higher, and still more preferably 5 mass % or higher. The upper limit is preferably 40 mass % or lower and more preferably 30 mass % or lower. The curable composition according to the embodiment of the present invention may include one resin or two or more kinds of resins. In a case where the curable composition includes two or more kinds of resins, it is preferable that the total content of the resins is in the above-described range.

In a case where the curable composition according to the embodiment of the present invention includes the polymerizable compound (preferably the monomer type polymerizable compound which has a group having an ethylenically unsaturated bond) and the resin, a mass ratio (polymerizable compound/resin) of the polymerizable compound to the resin is preferably 0.4 to 1.4. The lower limit of the mass ratio is preferably 0.5 or more and more preferably 0.6 or more. The upper limit of the mass ratio is preferably 1.3 or less and more preferably 1.2 or less. In a case where the mass ratio is in the above-described range, a pattern having more excellent rectangularity can be formed.

In addition, a mass ratio (polymerizable compound/resin having an acid group) of the polymerizable compound (preferably the monomer type polymerizable compound which has a group having an ethylenically unsaturated bond) to the resin having an acid group is preferably 0.4 to 1.4. The lower limit of the mass ratio is preferably 0.5 or more and more preferably 0.6 or more. The upper limit of the mass ratio is preferably 1.3 or less and more preferably 1.2 or less. In a case where the mass ratio is in the above-described range, a pattern having more excellent rectangularity can be formed.

<<Photopolymerization Initiator>>

The curable composition according to the embodiment of the present invention may include a photopolymerization initiator. Examples of the photopolymerization initiator include a photoradical polymerization initiator and a photocationic polymerization initiator. It is preferable that the photopolymerization initiator is selected and used according to the kind of the polymerizable compound. In a case where a radically polymerizable compound such as the compound which has a group having an ethylenically unsaturated bond is used as the polymerizable compound, it is preferable that a photoradical polymerization initiator is used as the photopolymerization initiator. In a case where the cationically polymerizable compound is used as the polymerizable compound, it is preferable that the photocationic polymerization initiator is used as the photopolymerization initiator. The photopolymerization initiator is not particularly limited and can be appropriately selected from well-known photopolymerization initiators. For example, a compound having photosensitivity to light in a range from an ultraviolet range to a visible range is preferable.

The content of the photopolymerization initiator is preferably 0.1 to 50 mass %, more preferably 0.5 to 30 mass %, and still more preferably 1 to 20 mass % with respect to the total solid content of the curable composition. In a case where the content of the photopolymerization initiator is in the above-described range, higher sensitivity and pattern formability can be obtained. The curable composition according to the embodiment of the present invention may include one photopolymerization initiator or two or more kinds of photopolymerization initiators. In a case where the curable composition includes two or more kinds of photopolymerization initiators, it is preferable that the total content of the photopolymerization initiators is in the above-described range.

(Photoradical Polymerization Initiator)

Examples of the photoradical polymerization initiator include a halogenated hydrocarbon derivative (for example, a compound having a triazine skeleton or a compound having an oxadiazole skeleton), an acyiphosphine compound, a hexaarylbiimidazole, an oxime compound, an organic peroxide, a thio compound, a ketone compound, an aromatic onium salt, an α-hydroxyketone compound, and an α-aminoketone compound. In addition, from the viewpoint of exposure sensitivity, as the photoradical polymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from the group consisting of an oxime compound, an α-hydroxy ketone compound, an α-aminoketone compound, and an acylphosphine compound is more preferable, and an oxime compound is still more preferable. The details of the photoradical polymerization initiator can be found in paragraphs “0065” to “0111” of JP2014-130173A, the content of which is incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF SE). Examples of a commercially available product of the α-aminoketone compound include IRGACURE-907, IRGACURE-369, IRGACURE-379, and IRGACURE-379EG (all of which are manufactured by BASF SE). Examples of a commercially available product of the acylphosphine compound include IRGACURE-819, and DAROCUR-TPO (all of which are manufactured by BASF SE).

Examples of the oxime compound include a compound described in JP2001-233842A, a compound described in JP2000-080068A, a compound described in JP2006-342166A, a compound described in J. C. S. Perkin II (1979, pp. 1653 to 1660), a compound described in J. C. S. Perkin II (1979, pp. 156 to 162), a compound described in Journal of Photopolymer Science and Technology (1995, pp. 202 to 232), a compound described in JP2000-066385A, a compound described in JP2000-080068A, a compound described in JP2004-534797A, a compound described in JP2006-342166A, a compound described in JP2017-019766A, a compound described in JP6065596B, a compound described in WO2015/152153A, and a compound described in WO2017/051680A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product of the oxime compound include IRGACURE-OXE01, IRGACURE-OXF02, IRGACURE-OXE03, or IRGACURE-OXE04 (all of which are manufactured by BASF SE), TR-PBG-304 (manufactured by Changzhou Tronly New Electronic Materials Co., Ltd.), and ADEKA OPTOMER N-1919 (manufactured by ADEKA Corporation, a photopolymerization initiator 2 described in JP2012-014052A). In addition, as the oxime compound, it is also preferable to use a compound having no colorability or a compound having high transparency and being difficult to discolor. Examples of a commercially available products include ADEKA ARKLS NCI-730, NCI-831, and NCI-930 (all of which are manufactured by ADEKA Corporation).

In the present invention, an oxime compound having a fluorene ring can also be used as the photoradical polymerization initiator. Specific examples of the oxime compound having a fluorene ring include a compound described in JP2014-137466A. The content is incorporated herein by reference.

In the present invention, an oxime compound having a fluorine atom can also be used as the photoradical polymerization initiator. Specific examples of the oxime compound having a fluorine atom include a compound described in JP2010-262028A, Compounds 24 and 36 to 40 described in JP2014-500852A, and Compound (C-3) described in JP2013-164471A. The content is incorporated herein by reference.

In the present invention, an oxime compound having a nitro group can be used as the photoradical polymerization initiator. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to “0025” of JP4223071B, and ADEKA ARKLS NCI-831 (manufactured by ADEKA Corporation).

In the present invention, an oxime compound having a benzofuran skeleton can also be used as the photoradical polymerization initiator. Specific examples thereof include OE-01 to OE-75 described in WO2015/036910A.

Specific examples of the oxime compound which are preferably used in the present invention are shown below, but the present invention is not limited thereto.

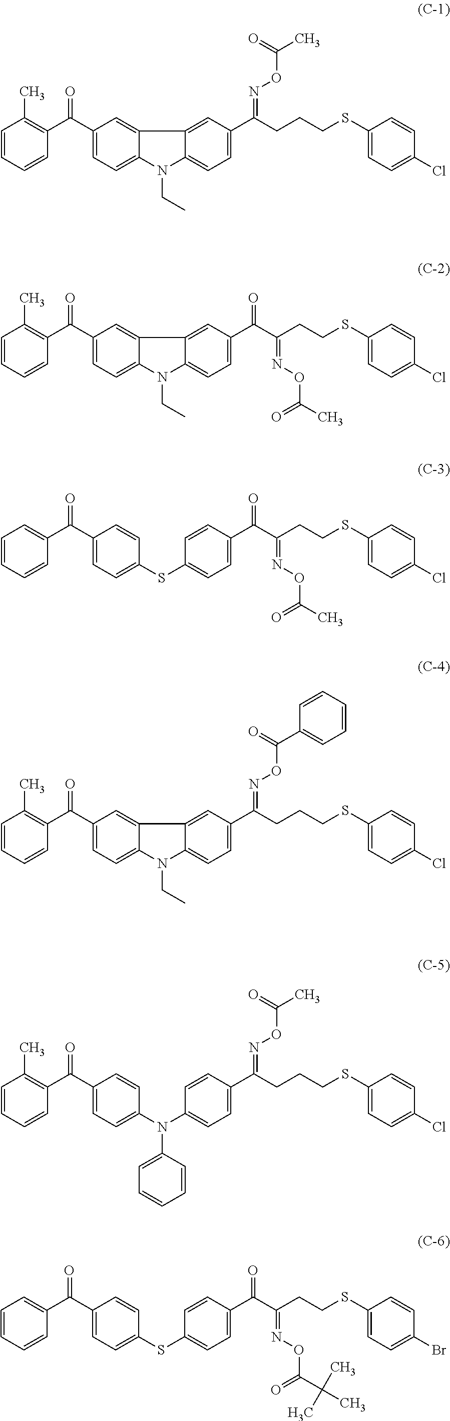 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

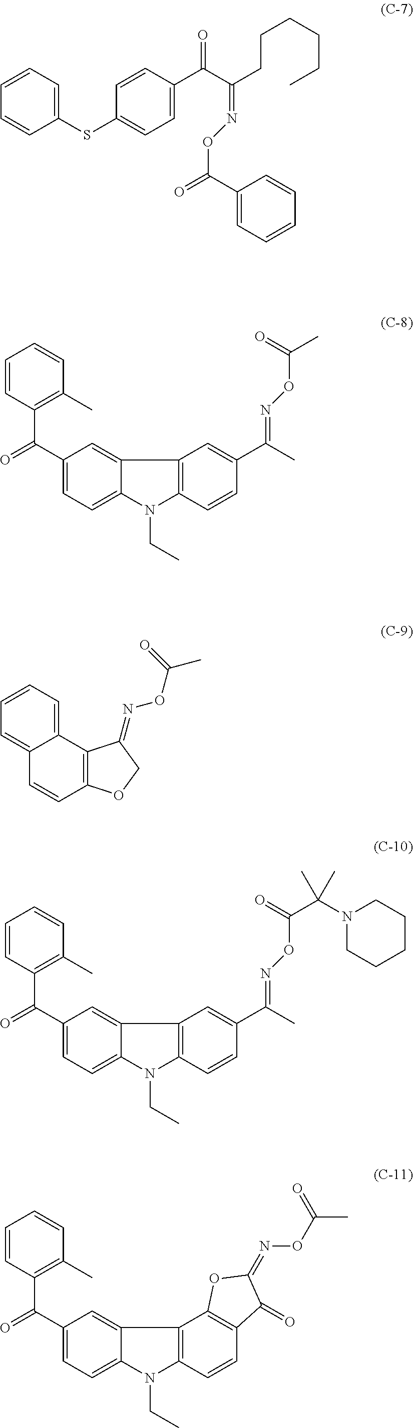 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

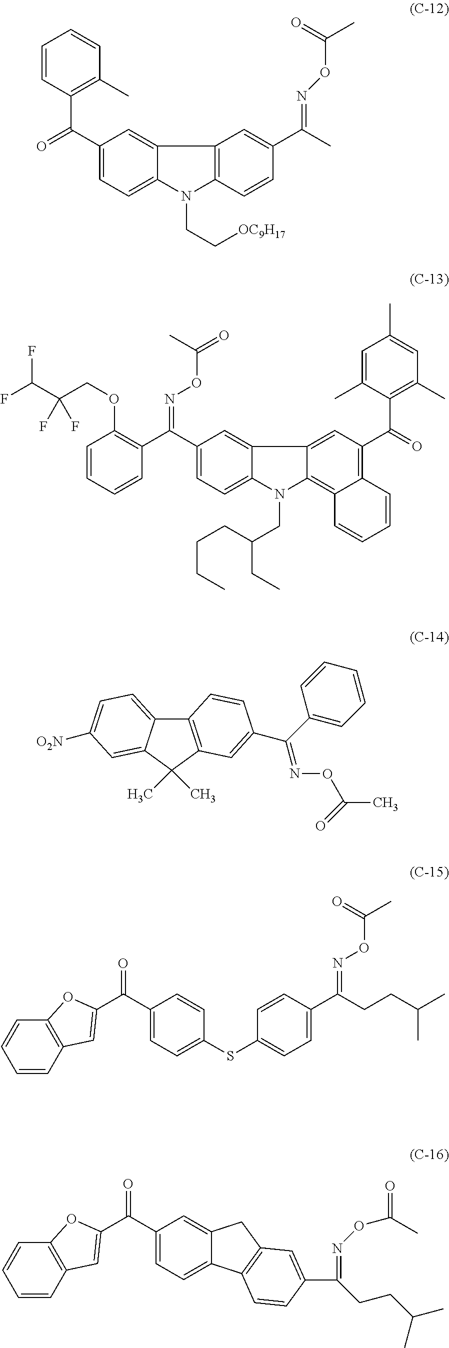

The oxime compound is preferably a compound having an absorption maximum wavelength in a range of 350 to 500 nm and more preferably a compound having an absorption maximum wavelength in a range of 360 to 480 nm. In addition, the molar absorption coefficient of the oxime compound at a wavelength of 365 nm or 405 nm is preferably high, more preferably 1,000 to 300,000, still more preferably 2,000 to 300,000, and particularly preferably 5,000 to 200,000 from the viewpoint of sensitivity. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

In the present invention, a difunctional or tri- or more functional photoradical polymerization initiator may be used as the photoradical polymerization initiator. Specific examples of such a photoradical polymerization initiator include a dimer of an oxime compound described in JP2010-527339A, JP2011-524436A, WO2015/004565A, paragraphs “0417” to “0412” of JP2016-532675A, or paragraphs “0039” to “0055” of WO2017/033680A, a compound (E) and a compound (G) described in JP2013-522445A, and Cmpd 1 to 7 described in WO2016/034963A.

It is preferable that the photoradical polymerization initiator includes an oxime compound and an α-aminoketone compound. By using the oxime compound and the α-aminoketone compound in combination, the developability is improved, and a pattern having excellent rectangularity is likely to be formed. In a case where the oxime compound and the α-aminoketone compound are used in combination, the content of the α-aminoketone compound is preferably 50 to 600 parts by mass and more preferably 150 to 400 parts by mass with respect to 100 parts by mass of the oxime compound.

The content of the photoradical polymerization initiator is preferably 0.1 to 50 mass %, more preferably 0.5 to 30 mass %, and still more preferably 1 to 20 mass % with respect to the total solid content of the curable composition according to the embodiment of the present invention. In a case where the content of the photoradical polymerization initiator is in the above-described range, higher sensitivity and pattern formability can be obtained. The curable composition according to the embodiment of the present invention may include one photoradical polymerization initiator or two or more kinds of photoradical polymerization initiators. In a case where the curable composition includes two or more kinds of photoradical polymerization initiators, it is preferable that the total content of the photoradical polymerization initiators is in the above-described range.

(Photocationic Polymerization Initiator)

Examples of the photocationic polymerization initiator include a photoacid generator. Examples of the photoacid generator include compounds which are decomposed by light irradiation to generate an acid including: an onium salt compound such as a diazonium salt, a phosphonium salt, a sulfonium salt, or an iodonium salt; and a sulfonate compound such as imidosulfonate, oximesulfonate, diazodisulfone, disulfone, or o-nitrobenzyl sulfonate. The details of the photocationic polymerization initiator can be found in paragraphs “0139” to “0214” of JP2009-258603A, the content of which is incorporated herein by reference.

The content of the photocationic polymerization initiator is preferably 0.1 to 50 mass %, more preferably 0.5 to 30 mass %, and still more preferably 1 to 20 mass % with respect to the total solid content of the curable composition according to the embodiment of the present invention. In a case where the content of the photocationic polymerization initiator is in the above-described range, higher sensitivity and pattern formability can be obtained. The curable composition according to the embodiment of the present invention may include one photocationic polymerization initiator or two or more kinds of photocationic polymerization initiators. In a case where the composition includes two or more kinds of photocationic polymerization initiators, it is preferable that the total content of the photocationic polymerization initiators is in the above-described range.

<<Polyfunctional Thiol>>

The curable composition according to the embodiment of the present invention may include a polyfunctional thiol. The polyfunctional thiol is a compound having two or more thiol (SH) groups. By using the above-described photoradical polymerization initiator in combination, the polyfunctional thiol functions as a chain transfer agent in the process of radical polymerization after light irradiation such that a thiyl radical that is not likely to undergo polymerization inhibition due to oxygen is generated. Therefore, the sensitivity of the curable composition according to the embodiment of the present invention can be improved. In particular, a polyfunctional aliphatic thiol in which the SH group is bonded to an aliphatic group such as an ethylene group is preferable.

Examples of the polyfunctional thiol include hexanedithiol, decanedithiol, 1,4-butanediol bisthio propionate, 1,4-butanediolbisthioglycolate, ethylene glycol bisthioglycolate, ethylene glycol bisthiopropionate, trimethylolpropane tristhioglycolate, trimethylolpropane tristhiopropionate, trimethylolethane tris(3-mercaptobutyrate), trimethylolpropane tris(3-mercaptobutyrate), trimethylolpropane tris(3-mercaptopropionate), pentaerythritol tetrakisthioglycolate, pentaerythritol tetrakisthiopropionate, pentaerythritol tetrakis(3-mercaptopropionate), dipentaerythritol hexakis(3-mercaptopropionate), trimercaptopropionic acid tris(2-hydroxyethyl)isocyanurate, 1,4-dimethylmercaptobenzene, 2,4,6-trimercapto-s-triazine, and 2-(N,N-dibutylamino)-4,6-dimercapto-s-triazine. In addition, for example, a compound having the following structure can also be used.

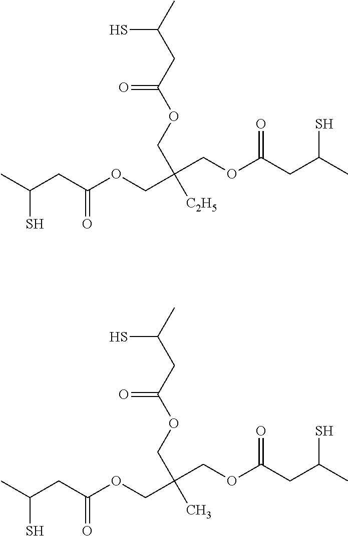

The content of the polyfunctional thiol is preferably 0.1 to 20 mass %, more preferably 0.1 to 15 mass %, and still more preferably 0.1 to 10 mass % with respect to the total solid content of the curable composition according to the embodiment of the present invention. The curable composition according to the embodiment of the present invention may include one polyfunctional thiol or two or more kinds of polyfunctional thiols. In a case where the curable composition includes two or more kinds of polyfunctional thiols, it is preferable that the total content of the polyfunctional thiols is in the above-described range.

<<Epoxy Resin Curing Agent>>

In a case where the curable composition according to the embodiment of the present invention includes an epoxy resin, it is preferable that the composition further includes an epoxy resin curing agent. Examples of the epoxy resin curing agent include an amine compound, an acid anhydride compound, an amide compound, a phenol compound, and a polycarboxylic acid. From the viewpoints of heat resistance and transparency of a cured product, as the epoxy resin curing agent, a polycarboxylic acid is preferable, and a compound having two or more carboxylic acid anhydride groups in a molecule is most preferable. Specific examples of the epoxy resin curing agent include butanedioic acid. The details of the epoxy resin curing agent can be found in paragraphs “0072” to “0078”, the content of which is incorporated herein by reference.

The content of the epoxy resin curing agent is preferably 0.01 to 20 parts by mass, more preferably 0.01 to 10 parts by mass, and still more preferably 0.1 to 6.0 parts by mass with respect to 100 parts by mass of the epoxy resin.

<<Pigment Derivative>>

The curable composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

PL-(X)ₙ)ₘ (B1)

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where in represents 2 or more, a plurality of L's and a plurality of X's may be different from each other, and in a case where n represents 2 or more, a plurality of X's may be different from each other.

The colorant structure represented by P is preferably at least one selected from a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, or a benzoxazole colorant structure, more preferably at least one selected from a pyrrolopyrrole colorant structure, a diketo pyrrolopyrrole colorant structure, a quinacridone colorant structure, or a benzimidazolone colorant structure, and still more preferably a pyrrolopyrrole colorant structure.

Examples of the linking group represented by L include a hydrocarbon group, a heterocyclic group, —NR—, —SO₂—, —S—, —O—, —CO—, or a group including a combination of the above-described groups. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and the heterocyclic group represented by R^{X1} to R^{X6} may further have a substituent. Examples of the substituent which may be further included include the above-described substituent T described in Formula (PP). Among these, a halogen atom is preferable and a fluorine atom is more preferable. Examples of the basic group represented by X include an amino group. Examples of the salt structure represented by X include a salt of the acid group or the basic group described above.

Examples of the pigment derivative include compounds having the following structures. In addition, for example, compounds described in JP1981-118462A (JP-S56-118462A), JP1988-264674A (JP-S63-264674A), JP1989-217077A (JP-1101-217077A), JP1991-009961A (JP-H03-009961 A), JP1991-026767A (JP-H03-026767 A), JP1991-153780 A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, paragraph “0082” of WO2017/038252A, and the like, or a compound described in JP5299151B can be used, the contents of which are incorporated herein by reference.

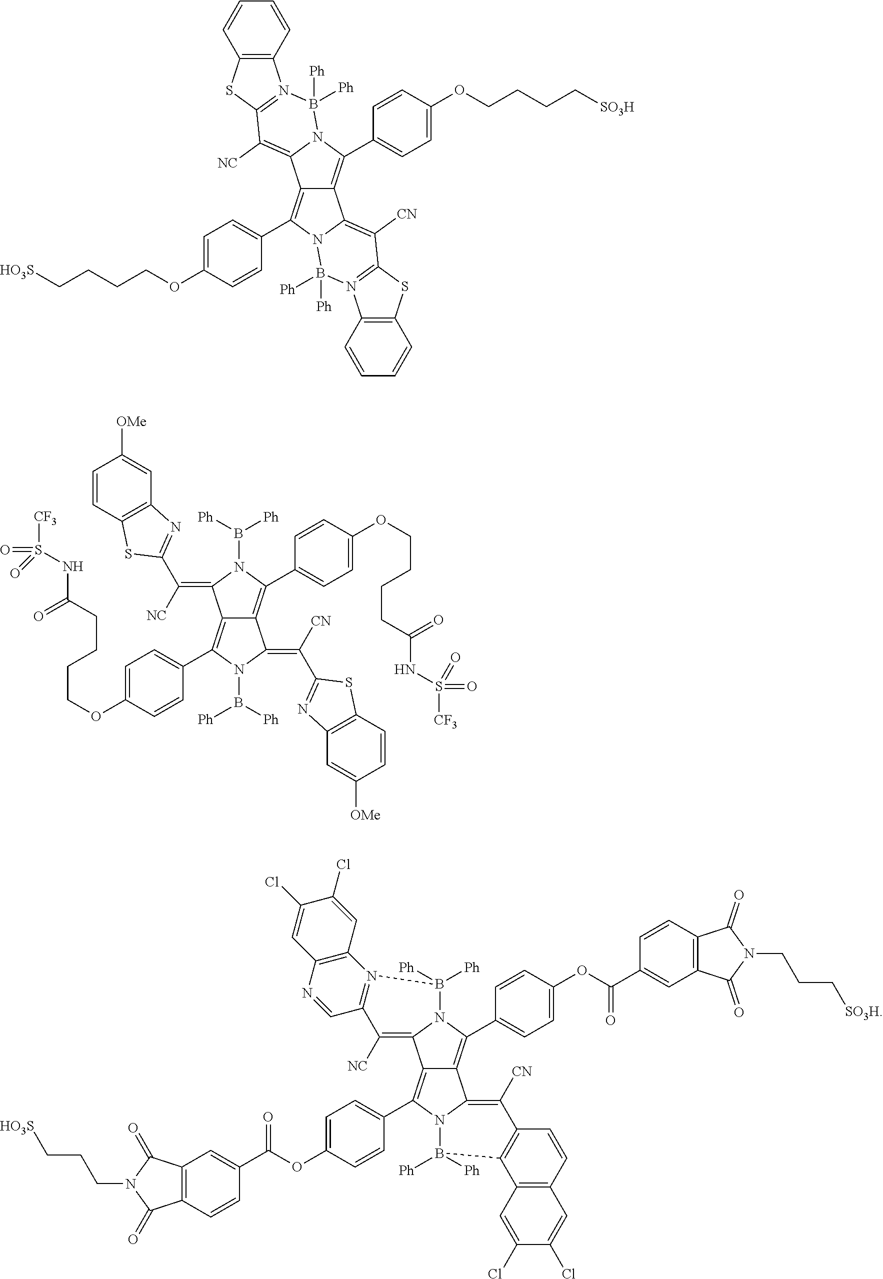

In a case where the curable composition according to the embodiment of the present invention includes a pigment derivative, the content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be efficiently suppressed. As the pigment derivative, one kind may be used alone, or two or more kinds may be used in combination. In a case where two or more kinds of pigment derivatives are used in combination, it is preferable that the total content of the two or more kinds of pigment derivatives is in the above-described range.

<<Solvent>>

The curable composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In addition, 3-methoxy-N,N-dimethylpropanamide and 3-butoxy-N,N-dimethylpropnamide are also preferable from the viewpoint of improving solubility. In this case, it may be preferable that the content of the aromatic hydrocarbons (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 μm or less, more preferably 5 μm or less, and still more preferably 3 μm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent is preferably 10 to 90 mass % with respect to the total mass of the curable composition according to the embodiment of the present invention. The lower limit is preferably 20 mass % or higher, more preferably 30 mass % or higher, still more preferably 40 mass % or higher, even more preferably 50 mass % or higher, and particularly preferably 60 mass % or higher.

<<Polymerization Inhibitory>

The curable composition according to the embodiment of the present invention may include a polymerization inhibitor. Examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The content of the polymerization inhibitor is preferably 0.001 to 5 mass % with respect to the total solid content of the curable composition according to the embodiment of the present invention.

<<Silane Coupling Agent>>

The curable composition according to the embodiment of the present invention may include a silane coupling agent. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than the hydrolyzable group include a vinyl group, a (meth)acryloyl group, a mercapto group, an epoxy group, an oxetanyl group, an amino group, an ureido group, a sulfide group, an isocyanate group, and a phenyl group. Among these, a (meth)acryloyl group or an epoxy group is preferable. Examples of the silane coupling agent include a compound described in paragraphs “0018” to “0036” of JP2009-288703A and a compound described in paragraphs “0056” to “0066” of JP2009-242604A, the content of which is incorporated herein by reference.

The content of the silane coupling agent is preferably 0.01 to 15 mass % and more preferably 0.05 to 10 mass % with respect to the total solid content of the curable composition according to the embodiment of the present invention. As the silane coupling agent, one kind may be used alone, or two or more kinds may be used. In a case where two or more kinds of silane coupling agents are used in combination, it is preferable that the total content of the two or more kinds of silane coupling agents is in the above-described range.

<<Surfactant>>

The curable composition according to the embodiment of the present invention may include a surfactant. As the surfactant, various surfactants such as a fluorine-based surfactant, a nonionic surfactant, a cationic surfactant, an anionic surfactant, or a silicone-based surfactant can be used. The details of the surfactant can be found in paragraphs “0238” to “0245” of WO2015/66779A, the content of which is incorporated herein by reference.

In the present invention, it is preferable that the surfactant is a fluorine-based surfactant. By the curable composition according to the embodiment of the present invention containing a fluorine-based surfactant, liquid characteristics (in particular, fluidity) are further improved, and liquid saving properties can be further improved. In addition, a film having reduced thickness unevenness can be formed.

The fluorine content in the fluorine-based surfactant is preferably 3 to 40 mass %, more preferably 5 to 30 mass %, and still more preferably 7 to 25 mass %. The fluorine-based surfactant in which the fluorine content is in the above-described range is effective from the viewpoints of the uniformity in the thickness of the coating film and liquid saving properties, and the solubility thereof in the composition is also excellent.

Specific examples of the fluorine-based surfactant include a surfactant described in paragraphs “0060” to “0064” of JP2014-041318A (corresponding to paragraphs “0060” to “0064” of WO2014/017669A) and a surfactant described in paragraphs “0117” to “0132” of JP2011-132503A, the content of which is incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound in which, in a case where heat is applied to a molecular structure which has a functional group having a fluorine atom, the functional group having a fluorine atom is cut and a fluorine atom is volatilized can also be preferably used. Examples of such a fluorine-based surfactant include MEGAFACE DS series (manufactured by D1C Corporation. The Chemical Daily, Feb. 22, 2016, Nikkei Business Daily, Feb. 23, 2016), for example, MEGAFACE DS-21.

In addition, the fluorine-based surfactant is also preferably a polymer of a fluorine atom-containing vinyl ether compound having a fluorinated alkyl group or a fluorinated alkylene ether group and a hydrophilic vinyl ether compound. The details of the fluorine-based surfactant can be found in the description of JP2016-216602A, the content of which is incorporated herein by reference.

As the fluorine-based surfactant, a block polymer can also be used. Examples of the block polymer include a compound described in JP2011-089090A. As the fluorine-based surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine-based surfactant used in the present invention.

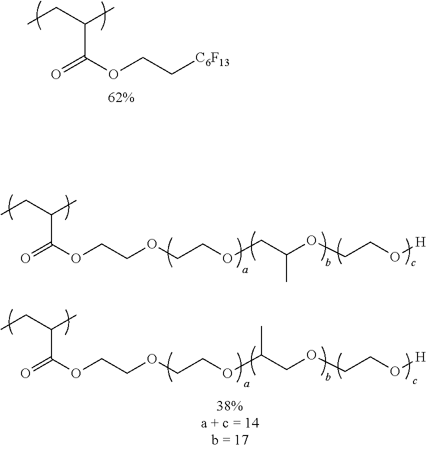

The weight-average molecular weight of the compound is preferably 3,000 to 50,000 and, for example, 14,000. In the compound, “%” representing the proportion of a repeating unit is mol %.

In addition, as the fluorine-based surfactant, a fluorine-containing polymer having an ethylenically unsaturated group in a side chain can also be used. Specific examples thereof include a compound described in paragraphs “0050” to “0090” and paragraphs “0289” to “0295” of JP2010-164965A, for example, MEGAFACE RS-101, RS-102, RS-71RK, and RS-72-K manufactured by D1C Corporation. As the fluorine-based surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrication Technology Inc.), NCW-101,NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

The content of the surfactant is preferably 0.001 mass % to 5.0 mass % and more preferably 0.005 to 3.0 mass % with respect to the total solid content of the curable composition according to the embodiment of the present invention. As the surfactant, one kind may be used alone, or two or more kinds may be used. In a case where two or more kinds of surfactants are used in combination, it is preferable that the total content of the two or more kinds of surfactants is in the above-described range.

<<Ultraviolet Absorber>>

The curable composition according to the embodiment of the present invention may include an ultraviolet absorber. As the ultraviolet absorber, a conjugated diene compound, an aminobutadiene compound, a methyldibenzoyl compound, a coumarin compound, a salicylate compound, a benzophenone compound, a benzotriazole compound, an acrylonitrile compound, an azomethine compound, an indole compound, or a triazine compound can be used. The details thereof can be found in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the conjugated diene compound include UV-503 (manufactured by Daito Chemical Co., Ltd.). Specific examples of the indole compound include compounds having the following structures. In addition, as the benzotriazole compound, MYUA series (manufactured by Miyoshi Oil&Fat Co., Ltd.: The Chemical Daily, Feb. 1, 2016) may be used.

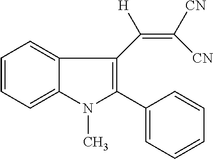 [SMILES: Cn1c(-c2ccccc2)c(C=C(C#N)C#N)c2ccccc21]

In the present invention, as the ultraviolet absorber, compounds represented by Formula (UV-1) to Formula (UV-3) can also be preferably used.

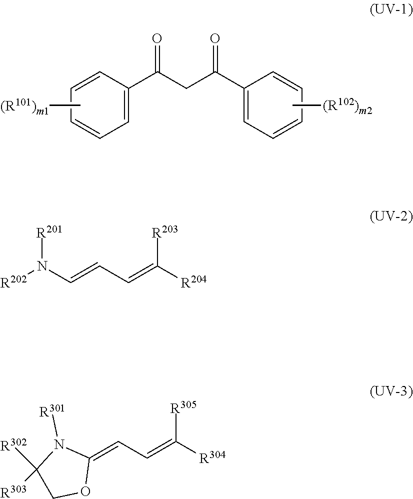

In Formula (UV-1), R¹⁰¹ and R¹⁰² each independently represent a substituent, and m1 and m2 each independently represent 0 to 4. In Formula (UV-2), R²⁰¹ and R²⁰² each independently represent a hydrogen atom or an alkyl group, and R²⁰³ and R²⁰⁴ each independently represent a substituent. In Formula (UV-3), R³⁰¹ to R³⁰³ each independently represent a hydrogen atom or an alkyl group, and R³⁰⁴ and R³⁰⁵ each independently represent a substituent.

Specific examples of the compounds represented by Formulae (UV-1) to (UV-3) include the following compounds.

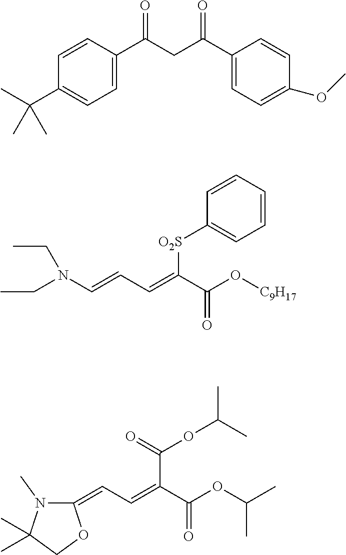

The content of the ultraviolet absorber is preferably 0.01 to 10 mass % and more preferably 0.01 to 5 mass % with respect to the total solid content of the curable composition according to the embodiment of the present invention. In the present invention, as the ultraviolet absorber, one kind may be used alone, or two or more kinds may be used. In a case where two or more kinds of ultraviolet absorbers are used in combination, it is preferable that the total content of the two or more kinds of ultraviolet absorbers is in the above-described range.

<<Antioxidant>>

The curable composition according to the embodiment of the present invention may include an antioxidant. Examples of the antioxidant include a phenol compound, a phosphite compound, and a thioether compound. As the phenol compound, any phenol compound which is known as a phenol-based antioxidant can be used. As the phenol compound, for example, a hindered phenol compound is preferable. A compound having a substituent at a position (ortho position) adjacent to a phenolic hydroxyl group is preferable. As the substituent, a substituted or unsubstituted alkyl group having 1 to 22 carbon atoms is preferable. In addition, as the antioxidant, a compound having a phenol group and a phosphite group in the same molecule is also preferable. In addition, as the antioxidant, a phosphorus-based antioxidant can also be preferably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADEKA STAB AO-20, ADEKA STAB AO-30, ADEKA STAB AO-40, ADEKA STAB AO-50, ADEKA STAB A0-50F, ADEKA STAB AO-60, ADEKA STAB AO-60G, ADEKA STAB AO-80, and ADEKA STAB AO-330 (all of which are manufactured by ADEKA Corporation). In addition, as the antioxidant, a polyfunctional hindered amine antioxidant described in WO17/006600A can also be used.

The content of the antioxidant is preferably 0.01 to 20 mass % and more preferably 0.3 to 15 mass % with respect to the total solid content of the curable composition according to the embodiment of the present invention. As the antioxidant, one kind may be used alone, or two or more kinds may be used in combination. In a case where two or more kinds of antioxidants are used in combination, it is preferable that the total content of the two or more kinds of antioxidants is in the above-described range.

<<Other Components>>

Optionally, the curable composition according to the embodiment of the present invention may further include a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By the curable composition appropriately including the components, properties such as film properties can be adjusted. The details of the components can be found in, for example, paragraph “0183” of JP2012-003225A (corresponding to paragraph “0237” of US2013/0034812A) and paragraphs “0101” to “0104” and “0107” to “0109” of JP2008-250074A, the content of which is incorporated herein by reference.

In addition, the curable composition according to the embodiment of the present invention may optionally include a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include a compound described in WO2014/021023A, WO2017/030005A, and JP2017-008219A. Examples of a commercially available product thereof include ADEKA ARKLS GPA-5001 (manufactured by ADEKA Corporation).

A storage container of the composition of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

The use of the curable composition according to the embodiment of the present invention is not particularly limited. The curable composition according to the embodiment of the present invention can be preferably used to form an infrared transmitting filter.

<Method of Preparing Curable Composition>

The curable composition according to the embodiment of the present invention can be prepared by mixing the above-described components with each other. During the preparation of the composition, all the components may be dissolved or dispersed in a solvent at the same time to prepare the composition. Optionally, two or more solutions or dispersion liquid to which the respective components are appropriately formulated may be prepared, and the solutions or dispersion liquid may be mixed with each other during use (during application) to prepare the composition.

In addition, in a case where the curable composition according to the embodiment of the present invention includes particles of a pigment or the like, it is preferable that a process of dispersing the particles is provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a microfluidizer, a high-speed impeller, a sand grinder, a project mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that coarse particles are removed by filtering after crushing, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the composition, it is preferable that the composition is filtered through a filter, for example, in order to remove foreign matters or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matters can be reliably removed. In addition, it is preferable that a fibrous filter material is used. Examples of the fibrous filter material include polypropylene fiber, nylon fiber, and glass fiber. Specific examples thereof include a filter cartridge of SBP type series (for example, SBP008), TPR type series (for example, TPR002 or TPR005), and SHPX type series (for example, SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more.

In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NIEY), Toyo Roshi Kaisha, Ltd., Entegris Japan Co., Ltd. (former Mykrolis Corporation), or Kits Microfilter Corporation.

The second filter may be formed of the same material as that of the first filter.

In addition, the filtering using the first filter may be performed only on the dispersion liquid, and the filtering using the second filter may be performed on a mixture of the dispersion liquid and other components.

The total solid content (concentration of solid contents) of the curable composition according to the embodiment of the present invention changes depending on a coating method and, for example, is preferably 1 to 50 mass %. The lower limit is more preferably 10 mass % or higher. The upper limit is more preferably 30 mass % or lower.

In a case where a film is formed using the curable composition according to the embodiment of the present invention such that the thickness of the film after drying is 0.1 to 50 μm (preferably 0.1 to 20 μm and more preferably 0.5 to 10 μm), it is preferable that the film satisfies the following spectral characteristics in at least one of the above-described thicknesses: that a maximum value of a transmittance in a wavelength range of 300 to 380 nm is 10% or higher (preferably 15% or higher and more preferably 20% or higher); that a maximum value of a transmittance in a wavelength range of 420 to 650 nm is 20% or lower (preferably 15% or lower and more preferably 10% or lower); and that a maximum value of a transmittance in a wavelength range of 1000 to 1300 nm is 70% or higher (preferably 75% or higher and more preferably 80% or higher).

In addition, in a case where a film is formed using the curable composition according to the embodiment of the present invention such that the thickness of the film after drying is 0.1 to 50 μm (preferably 0.1 to 20 μm and more preferably 0.5 to 10 μm), it is more preferable that the film satisfies any one of the following spectral characteristics in at least one of the above-described thicknesses.

(1) A maximum value of a transmittance in a wavelength range of 300 to 380 nm is 10% or higher (preferably 15% or higher and more preferably 20% or higher), a maximum value of a transmittance in a wavelength range of 420 to 650 nm is 20% or lower (preferably 15% or lower and more preferably 10% or lower), and a maximum value of a transmittance in a wavelength range of 800 to 1300 nm is 70% or higher (preferably 75% or higher and more preferably 80% or higher).

(2) A maximum value of a transmittance in a wavelength range of 300 to 380 nm is 10% or higher (preferably 15% or higher and more preferably 20% or higher), a maximum value of a transmittance in a wavelength range of 420 to 750 nm is 20% or lower (preferably 15% or lower and more preferably 10% or lower), and a maximum value of a transmittance in a wavelength range of 900 to 1300 nm is 70% or higher (preferably 75% or higher and more preferably 80% or higher).

(3) A maximum value of a transmittance in a wavelength range of 300 to 380 nm is 10% or higher (preferably 15% or higher and more preferably 20% or higher), a maximum value of a transmittance in a wavelength range of 420 to 830 nm is 20% or lower (preferably 15% or lower and more preferably 10% or lower), and a maximum value of a transmittance in a wavelength range of 1000 to 1300 nm is 70% or higher (preferably 75% or higher and more preferably 80% or higher).

A film formed of the curable composition according to the embodiment of the present invention can be preferably used as an infrared transmitting filter.

<Pattern Forming Method>

Next, a pattern forming method using the curable composition according to the embodiment of the present invention will be described. It is preferable that a pattern forming method includes: a step of forming a composition layer on a support using the curable composition according to the embodiment of the present invention; and a step of forming a pattern on the composition layer using a photolithography method or a dry etching method.

It is preferable that the formation of a pattern using the photolithography method includes: a step of forming a composition layer on a support using the curable composition according to the embodiment of the present invention; a step of exposing the composition layer in a pattern shape; and a step of forming a pattern by removing a non-exposed area by development. In addition, the formation of a pattern using a dry etching method can be performed using a method including: forming a composition layer on a support using the curable composition according to the embodiment of the present invention; curing the composition layer formed on the support to form a cured composition layer; forming a patterned resist layer on the cured composition layer; and dry-etching the cured composition layer with etching gas by using the patterned resist layer as a mask. Hereinafter, the respective steps will be described.

<<Step of Forming Composition Layer>>

In the step of forming a composition layer, a composition layer using the curable composition according to the embodiment of the present invention is formed on a support. Examples of the support include a substrate formed of a material such as silicon, non-alkali glass, soda glass, PYREX (registered trade name) glass, or quartz glass. In addition, for example, an InGaAs substrate is preferably used. The InGaAs substrate has excellent sensitivity to light having a wavelength of longer than 1000 nm. Therefore, by laminating the film according to the embodiment of the present invention on the InGaAs substrate, an optical sensor having excellent sensitivity can be easily obtained. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat.

As a method of applying the composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint method. The application method using an ink jet method is not particularly limited, and examples thereof include a method (in particular, pp. 115 to 133) described in “Extension of Use of Ink Jet—Infinite Possibilities in Patent—” (February, 2005, S. B. Research Co., Ltd.) and methods described in JP2003-262716A, JP2003-185831A, JP2003-261827A, JP2012-126830A, and JP2006-169325A. In addition, the details of the method of applying the resin composition can be found in WO2017/030174A and WO2017/018419A, the contents of which are incorporated herein by reference.

The composition layer formed on the support may be dried (pre-baked). In a case where a pattern is formed through a low-temperature process, pre-baking is not necessarily performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 3000 seconds, more preferably 40 to 2500 seconds, and still more preferably 80 to 2200 seconds. Drying can be performed using a hot plate, an oven, or the like.

(Case where Pattern is Formed Using Photolithography Method)

<<Exposure Step>>

Next, the composition layer is exposed in a pattern shape (exposure step). For example, the composition layer can be exposed in a pattern shape using an exposure device such as a stepper through a mask having a predetermined mask pattern. As a result, an exposed portion can be cured. As radiation (light) used during the exposure, ultraviolet light such as g-rays or i-rays is preferable, and i-rays are more preferable. The irradiation dose (exposure dose) is preferably 0.03 to 2.5 J/cm², more preferably 0.05 to 1.0 J/cm², and most preferably 0.08 to 0.5 J/cm². The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %). In addition, the exposure illuminance can be appropriately set and typically can be selected in a range of 1000 W/m² to 100000 W/m² (for example, 5000 W/m², 15000 W/m², or 35000 W/m²). Conditions of the oxygen concentration and the exposure illuminance may be appropriately combined. For example, conditions are oxygen concentration: 10 vol % and illuminance: 10000 W/m², or oxygen concentration: 35 vol % and illuminance: 20000 W/m².

<<Development Step>>

Next, a pattern is formed by removing a non-exposed area of the exposed composition layer by development. The non-exposed area of the composition layer can be removed by development using a developer. As a result, a non-exposed area of the composition layer in the exposure step is eluted into the developer, and only the photocured portion remains on the support. As the developer, an alkali developer which does not cause damages to a solid image pickup element as an underlayer, a circuit or the like is desired. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

Examples of the alkaline agent used as the developer include: an organic alkaline compound such as ethylarnine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as ammonia water, sodium hydroxide, potassium hydroxide, sodium carbonate, sodium bicarbonate, sodium silicate, or sodium metasilicate. In consideration of environmental aspects and safety aspects, the alkaline agent is preferably a compound having a high molecular weight. As the developer, an alkaline aqueous solution in which the above alkaline agent is diluted with pure water is preferably used. A concentration of the alkaline agent in the alkaline aqueous solution is preferably 0.001 to 10 mass % and more preferably 0.01 to 1 mass %. In addition, a surfactant may be used for the developer. Examples of the surfactant include the surfactants described above. Among these, a nonionic surfactant is preferable. From the viewpoint of easiness of transport, storage, and the like, the developer may be obtained by temporarily producing a concentrated solution and diluting the concentrated solution to a necessary concentration during use. The dilution factor is not particularly limited and, for example, can be set to be in a range of 1.5 to 100 times. In a case where a developer including the alkaline aqueous solution is used, it is preferable that the layer is washed (rinsed) with pure water after development.

In the present invention, after the development step and the drying, a heat treatment (post-baking) or a curing step of curing the film by post-exposure may be performed.

Post-baking is a heat treatment which is performed after development for completely curing. The heating temperature in the post-baking is, for example, preferably 100° C. to 240° C. and more preferably 200° C. to 240° C. In addition, in a case where an organic electroluminescence (organic EL) element is used as a light-emitting light source, or in a case where a photoelectric conversion film of an image sensor is formed of an organic material, the heating temperature is preferably 150° C. or lower, more preferably 120° C. or lower, still more preferably 100° C. or lower, and particularly preferably 90° C. or lower. The lower limit may be, for example, 50° C. or higher. The film after the development is post-baked continuously or batchwise using heating means such as a hot plate, a convection oven (hot air circulation dryer), and a high-frequency heater under the above-described conditions.

Regarding post-exposure, for example, g-rays, h-rays, i-rays, excimer lasers such as KrF or ArF, electron beams, or X-rays can be used. It is preferable that post-baking is performed using an existing high-pressure mercury lamp at a low temperature of about 20° C. to 50° C. The irradiation time is 10 seconds to 180 seconds and preferably 30 seconds to 60 seconds. In a case where post-exposure and post-heating are performed in combination, it is preferable that post-exposure is performed before post-heating.

(Case where Pattern is Formed Using Dry Etching Method)

The formation of a pattern using a dry etching method can be performed using a method including: curing the composition layer on the support to form a cured composition layer; forming a patterned resist layer on the cured composition layer; and dry-etching the cured composition layer with etching gas by using the patterned resist layer as a mask. As the forming process of the resist layer, it is desirable that a heat treatment after exposure and a heat treatment after development (post-baking treatment) are performed. The details of the pattern formation using the dry etching method can be found in paragraphs “0010” to “0067” of JP2013-064993A, the content of which is incorporated herein by reference.

By performing the respective steps as described above, a pattern (pixel) of the film having the specific spectral characteristics according to the embodiment of the present invention can be formed.

<Film>

Next, a film according to the embodiment of the present invention will be described.

The film according to the embodiment of the present invention includes 20 to 70 mass % of a coloring material, in which a content of a compound in which a ratio D1/D2 of an absorbance D1 at a wavelength of 365 nm to a maximum value D2 of an absorbance in a wavelength range of 420 to 1000 nm is 0.6 or lower in the coloring material is 95 mass % or higher with respect to a total mass of the coloring material, a maximum value of a transmittance in a wavelength range of 300 to 380 nm is 10% or higher, a maximum value of a transmittance in a wavelength range of 420 to 650 nm is 20% or lower, and a maximum value of a transmittance in a wavelength range of 1000 to 1300 nm is 70% or higher.

Examples of the coloring material included in the film according to the embodiment of the present invention include the above-described materials. The film according to the embodiment of the present invention can be preferably used as an infrared transmitting filter.

In addition, another aspect of the film according to the embodiment of the present invention is a film that is obtained using the curable composition according to the embodiment of the present invention.

The film according to the embodiment of the present invention can allow transmission of ultraviolet light and infrared light in a state where noise derived from visible light is small. By incorporating the film into an optical sensor or the like, sensing using infrared light and sensing using ultraviolet light can be simultaneously performed. In addition, in a case where ultraviolet light is used, for example, the surface state of a target can be observed with a higher accuracy as compared to a case where visible light is used. It is preferable that the film according to the embodiment of the present invention has at least one of the following spectral characteristics (1) to (3).

(1) A maximum value of a transmittance in a wavelength range of 300 to 380 nm is 10% or higher (preferably 15% or higher and more preferably 20% or higher), a maximum value of a transmittance in a wavelength range of 420 to 650 nm is 20% or lower (preferably 15% or lower and more preferably 10% or lower), and a maximum value of a transmittance in a wavelength range of 800 to 1300 nm is 70% or higher (preferably 75% or higher and more preferably 80% or higher). According to this aspect, the film can block light in a wavelength range of 420 to 650 nm and can allow transmission of light in a wavelength range of 300 to 380 nm and light having a wavelength of longer than 750 nm.

(2) A maximum value of a transmittance in a wavelength range of 300 to 380 nm is 10% or higher (preferably 15% or higher and more preferably 20% or higher), a maximum value of a transmittance in a wavelength range of 420 to 750 nm is 20% or lower (preferably 15% or lower and more preferably 10% or lower), and a maximum value of a transmittance in a wavelength range of 900 to 1300 nm is 70% or higher (preferably 75% or higher and more preferably 80% or higher). According to this aspect, the film can block light in a wavelength range of 420 to 750 nm and can allow transmission of light in a wavelength range of 300 to 380 nm and light having a wavelength of longer than 850 nm.

(3) A maximum value of a transmittance in a wavelength range of 300 to 380 nm is 10% or higher (preferably 15% or higher and more preferably 20% or higher), a maximum value of a transmittance in a wavelength range of 420 to 830 nm is 20% or lower (preferably 15% or lower and more preferably 10% or lower), and a maximum value of a transmittance in a wavelength range of 1000 to 1300 nm is 70% or higher (preferably 75% or higher and more preferably 80% or higher). According to this aspect, the film can block light in a wavelength range of 420 to 830 nm and can allow transmission of light in a wavelength range of 300 to 380 nm and light having a wavelength of longer than 900 nm.

The thickness of the film according to the embodiment of the present invention is not particularly limited and is preferably 0.1 to 50 μm, more preferably 0.1 to 20 μm, and still more preferably 0.5 to 10 μm.

<Infrared Transmitting Filter>

Next, an infrared transmitting filter according to the embodiment of the present invention will be described. The infrared transmitting filter according to the embodiment of the present invention includes the film according to the embodiment of the present invention. It is preferable that the infrared transmitting filter according to the embodiment of the present invention is laminated on a support for use. Examples of the support include the above-described examples.

The infrared transmitting filter according to the embodiment of the present invention can be used in combination with a color filter that includes a chromatic colorant. The color filter can be produced using a coloring composition including a chromatic colorant. The coloring composition may further include a resin, a polymerizable compound, a photopolymerization initiator, a surfactant, a solvent, a polymerization inhibitor, and an ultraviolet absorber. In more detail, for example, the materials described above regarding the curable composition according to the embodiment of the present invention can be used.

<Solid Image Pickup Element>

A solid image pickup element according to the embodiment of the present invention includes the film according to the embodiment of the present invention. The configuration of the solid image pickup element according to the embodiment of the present invention is not particularly limited as long as it includes the film according to the embodiment of the present invention and functions as a solid image pickup element. For example, the following configuration can be adopted.

The solid image pickup element (CCD image sensor, CMOS image sensor, and the like) includes a plurality of photodiodes and transfer electrodes on the support, the photodiodes constituting a light receiving area of the solid image pickup element, and the transfer electrode being formed of polysilicon or the like. In the solid image pickup element, a light blocking film formed of tungsten or the like which has openings through only light receiving sections of the photodiodes is provided on the photodiodes and the transfer electrodes, a device protective film formed of silicon nitride or the like is formed on the light blocking film so as to cover the entire surface of the light blocking film and the light receiving sections of the photodiodes, and the film according to the embodiment of the present invention or a laminate is formed on the device protective film. Further, a configuration in which light collecting means (for example, a microlens; hereinafter, the same shall be applied) is provided above the device protective film and below the film according to the embodiment of the present invention or the laminate (on a side thereof close the support), or a configuration in which light collecting means is provided on the film according to the embodiment of the present invention or the laminate may be adopted.

<Optical Sensor>

An optical sensor according to the embodiment of the present invention includes the film according to the embodiment of the present invention. The configuration of the optical sensor is not particularly limited as long as it functions as an optical sensor. Hereinafter, an embodiment of the optical sensor according to the embodiment of the present invention will be described using the drawings.

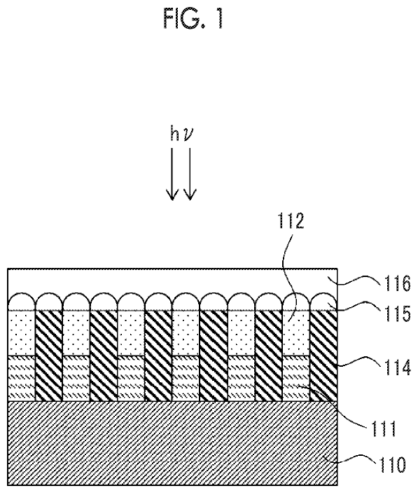

In FIG. 1, reference numeral 110 represents a solid image pickup element. In an imaging region provided on a solid image pickup element 110, near infrared cut filters 111 and infrared transmitting filters 114 are provided. In addition, color filters 112 are laminated on the near infrared cut filters 111. Microlenses 115 are disposed on an incidence ray hv side of the color filters 112 and the infrared transmitting filters 114. A planarizing layer 116 is formed so as to cover the microlenses 115.

The near infrared cut filters 111 are filters that allow transmission of light in a visible range (for example, light in a wavelength range of 400 to 700 nm) and block light in an infrared range. The color filters 112 are not particularly limited as long as pixels which allow transmission of light having a specific wavelength in a visible range and absorb the light are formed therein, and well-known color filters in the related art for forming a pixel can be used. For example, a color filter in which pixels of red (R), green (G), and blue (B) are formed is used. For example, the details of the color filters can be found in paragraphs “0214” to “0263” of JP2014-043556A, the content of which is incorporated herein by reference. The infrared transmitting filters 114 have visible light blocking properties, allow transmission of infrared light having a specific wavelength, and are formed of the film according to the embodiment of the present invention having the above-described spectral characteristics.

In the optical sensor shown in FIG. 1, a near infrared cut filter (other near infrared cut filter) other than the near infrared cut filter 111 may be further disposed on the planarizing layer 116. As the other near infrared cut filter, for example, a layer containing copper and/or a dielectric multi-layer film may be provided. The details of the examples are as described above. In addition, as the other near infrared cut filter, a dual band pass filter may be used.

In addition, in the embodiment shown in FIG. 1, the color filters 112 are provided on the incidence ray hv side compared to the near infrared cut filter 111. The lamination order of the near infrared cut filter 111 and the color filters 112 may be reversed, and the near infrared cut filter 111 may be provided on the incidence ray hv side compared to the color filters 112.

In addition, in the embodiment shown in FIG. 1, the near infrared cut filters 111 and the color filters 112 are laminated adjacent to each other. However, the infrared cut filters 111 and the color filters 112 are not necessarily provided adjacent to each other, and another layer may be provided therebetween.

<Image Display Device>

The film or the laminate according to the embodiment of the present invention can also be used in an image display device such as a liquid crystal display device or an organic electroluminescence (organic EL) display device. The definition of a display device and details of each display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.).

In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The type of the liquid crystal display device to which the present invention is applicable is not particularly limited. For example, the present invention is applicable to various liquid crystal display devices described in “Next-Generation Liquid Crystal Display Techniques”.

The image display device may be an image display device having a white organic EL element as a display element. It is preferable that the white organic EL element has a tandem structure. The tandem structure of the organic EL element is described in, for example, JP2003-045676A, or pp. 326 to 328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

### EXAMPLES

Hereinafter, the present invention will be described in more detail using examples. However, the present invention is not limited to the following examples as long as it does not depart from the gist of the present invention. Unless specified otherwise, “part(s)” and “%” represent “part(s) by mass” and “mass %”. In addition, the absorbance of a coloring material was calculated by forming a film in which the content of the coloring material as a measurement target was 50 mass % using a composition including the coloring material as a measurement target and a resin B-1 described below on glass and measuring an absorbance of the above-described film in a wavelength range of 300 to 1300 nm. As a measuring device, a spectrophotometer U-4100 (manufactured by Hitachi High-Technologies Corporation) was used. The thickness of the film was 0.5 μm.

<Preparation of Dispersion Liquid>

Raw materials shown in Table 1 below were mixed with each other, 230 parts by mass of zirconia beads having a diameter of 0.3 mm were further added to the mixture, and the solution was dispersed using a paint shaker for 5 hours. Next, the beads were separated by filtration. As a result, a dispersion liquid was produced. Numerical values in the following table are represented by “part(s) by mass”.

TABLE 1

| | | Dispersion | Dispersion | Dispersion | Dispersion | Dispersion | Dispersion | Dispersion | Dispersion | Dispersion | Dispersion |
|---|---|---|---|---|---|---|---|---|---|---|---|
| | | liquid R-1 | liquid V-1 | liquid Bk-1 | liquid Bk-2 | liquid Bk-3 | liquid Bk-4 | liquid IR-1 | liquid IR-2 | liquid Y-1 | liquid B-1 |
| Coloring | PR254 | 12 | | | | | | | | | |
| material | PV23 | | 12 | | | | | | | | |
| | PBk31 | | | 12 | | | | | | | |
| | PBk32 | | | | 12 | | | | | | |
| | Black | | | | | 12 | | | | | |
| | coloring | | | | | | | | | | |
| | material | | | | | | | | | | |
| | IB | | | | | | 12 | | | | |
| | Pig1 | | | | | | | 10.8 | | | |
| | Pig2 | | | | | | | | 10.8 | | |
| | PY139 | | | | | | | | | 12 | |
| | PB15:6 | | | | | | | | | | 12 |
| Pigment | syn1 | | | | | | | 1.2 | 1.2 | | |
| derivative | | | | | | | | | | | |
| Dispersant | A-1 | | | | | | | 4.2 | 4.2 | | |
| | A-2 | 4.2 | 4.2 | 4.2 | 4.2 | 4.2 | 4.2 | | | 4.2 | 4.2 |
| Solvent | S-1 | 83.8 | 83.8 | 83.8 | 83.8 | 83.8 | 83.8 | 83.8 | 83.8 | 83.8 | 83.8 |

<Preparation of Curable Composition>

Raw materials shown in Table 2 were mixed with each other to prepare a curable composition. Numerical values in the following table are represented by “part(s) by mass”.

TABLE 2

| | | | | | | | | | | Com- | Com- | Com- |
|---|---|---|---|---|---|---|---|---|---|---|---|---|
| | | | | | | | | | | par- | par- | par- |
| | | | | | | | | | | ative | ative | ative |
| | | Exam- | Exam- | Exam- | Exam- | Exam- | Exam- | Exam- | Exam- | Exam- | Exam- | Exam- |
| | | ple 1 | ple 2 | ple 3 | ple 4 | ple 5 | ple 6 | ple 7 | ple 8 | ple 1 | ple 2 | ple 3 |
| Disper- | Disper- | 22.50 | 7.50 | 7.50 | 7.50 | 3.00 | 3.00 | 3.00 | 3.00 | | 15.00 | |
| sion | sion | | | | | | | | | | | |
| liquid | liquid | | | | | | | | | | | |
| | R-1 | | | | | | | | | | | |
| | Disper- | | 7.50 | 7.50 | 7.50 | 7.50 | 7.50 | 7.50 | 7.50 | 51.00 | | |
| | sion | | | | | | | | | | | |
| | liquid | | | | | | | | | | | |
| | V-1 | | | | | | | | | | | |
| | Disper- | 60.00 | | | | | | | 16.50 | | | |
| | sion | | | | | | | | | | | |
| | liquid | | | | | | | | | | | |
| | Bk-1 | | | | | | | | | | | |
| | Disper- | | 75.00 | | 75.00 | 45.00 | 45.00 | 18.00 | | | 22.50 | |
| | sion | | | | | | | | | | | |
| | liquid | | | | | | | | | | | |
| | Bk-2 | | | | | | | | | | | |
| | Disper- | | | 75.00 | | | | | | | | |
| | sion | | | | | | | | | | | |
| | liquid | | | | | | | | | | | |
| | BK-3 | | | | | | | | | | | |
| | Disper- | | | | | | | | | | | 60.00 |
| | sion | | | | | | | | | | | |
| | liquid | | | | | | | | | | | |
| | Bk-4 | | | | | | | | | | | |
| | Disper- | | | | | 22.50 | | | 15.00 | | | |
| | sion | | | | | | | | | | | |
| | liquid | | | | | | | | | | | |
| | IR-1 | | | | | | | | | | | |
| | Disper- | | | | | | | | 6.00 | | | |
| | sion | | | | | | | | | | | |
| | liquid | | | | | | | | | | | |
| | IR-2 | | | | | | | | | | | |
| | Disper- | | | | | | | | | 25.05 | 12.00 | |
| | sion | | | | | | | | | | | |
| | liquid | | | | | | | | | | | |
| | Y-1 | | | | | | | | | | | |
| | Disper- | | | | | | | | | | 18.00 | 15.00 |
| | sion | | | | | | | | | | | |
| | liquid | | | | | | | | | | | |
| | B-1 | | | | | | | | | | | |
| Coloring | Dye 1 | | | | | | 2.70 | | | | | |
| material | Dye 2 | | | | | | | 2.70 | | | | |
| Resin | B-1 | 1.26 | 0.45 | 0.45 | 0.45 | 0.72 | 0.72 | 0.72 | 0.72 | 0.72 | | |
| | B-2 | | 0.63 | 0.63 | | | 0.95 | 0.95 | | | 0.72 | 1.80 |
| | B-3 | | | | 0.63 | | | | | | | |
| Polymer- | C-1 | 1.98 | 1.08 | 1.08 | 1.08 | 0.36 | 0.36 | 0.36 | 0.36 | 2.70 | 0.36 | 0.51 |
| izable | C-2 | | 1.08 | 1.08 | 1.08 | 1.98 | 1.98 | 1.98 | 1.98 | | 1.98 | 2.16 |
| compound | | | | | | | | | | | | |
| Photo- | D-1 | 0.90 | 0.52 | 0.52 | 0.52 | 0.72 | 0.72 | 0.72 | 0.72 | 0.72 | 0.72 | 1.44 |
| poly- | D-2 | | 0.38 | 0.38 | 0.38 | 0.36 | 0.36 | 0.36 | 0.36 | | 0.36 | |
| merization | | | | | | | | | | | | |
| initiator | | | | | | | | | | | | |
| Surfactant | E-1 | 0.04 | 0.04 | 0.04 | 0.04 | 0.04 | 0.04 | 0.04 | 0.04 | 0.04 | 0.04 | 0.04 |
| Polymer- | F-1 | 0.001 | 0.001 | 0.001 | 0.001 | 0.001 | 0.001 | 0.001 | | 0.001 | 0.001 | 0.001 |
| ization | | | | | | | | | | | | |
| inhibitor | | | | | | | | | | | | |
| Solvent | S-1 | 13.32 | 5.82 | 5.82 | 5.82 | 17.82 | | | 29.82 | 19.77 | 28.32 | 19.05 |
| | S-2 | | | | | | 36.82 | 36.82 | | | | |

The raw materials shown above in Tables 1 and 2 are as follows. In the following structural formulae, Me represents a methyl group, and Ph represents a phenyl group.

### (Coloring Material)

Pig 1: a compound having the following structure. Pig 1 is a near infrared absorbing colorant that is a compound in which a ratio D1/D2 of an absorbance D1 at a wavelength of 365 nm to a maximum value D2 of an absorbance in a wavelength range of 420 to 1000 nm is 0.6 or lower.

Pig 2: a compound having the following structure. Pig 2 is a near infrared absorbing colorant that is a compound in which a ratio D1/D2 of an absorbance D1 at a wavelength of 365 nm to a maximum value D2 of an absorbance in a wavelength range of 420 to 1000 nm is 0.6 or lower.

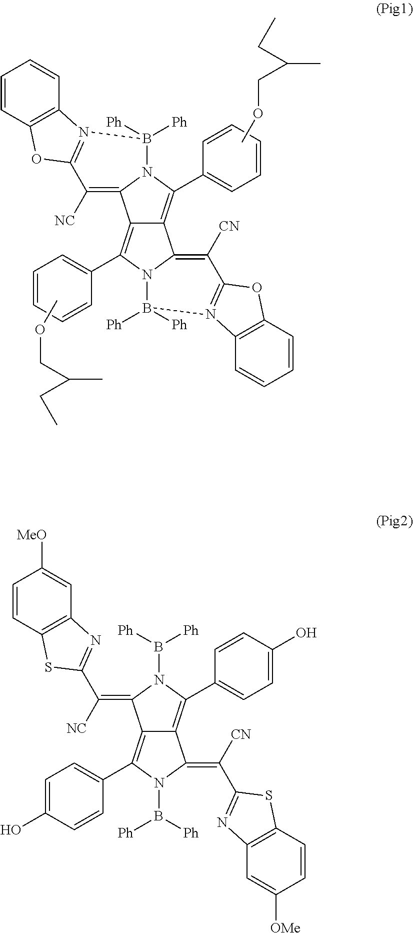

Dye 1: a compound having the following structure. Dye 1 is a near infrared absorbing colorant that is a compound in which a ratio D1/D2 of an absorbance D1 at a wavelength of 365 nm to a maximum value D2 of an absorbance in a wavelength range of 420 to 1000 nm is 0.6 or lower.

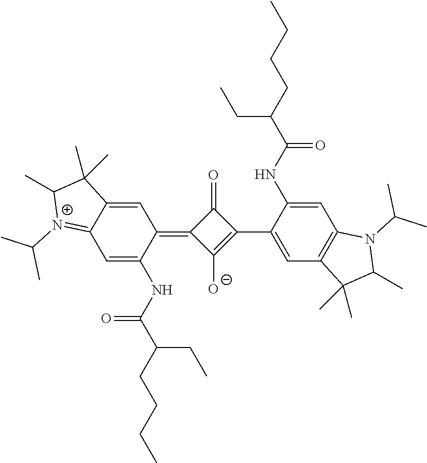 [SMILES: CCCCC(CC)C(=O)Nc1cc2c(cc1C1=C([O-])/C(=c3/cc4c(cc3NC(=O)C(CC)CCCC)=[N+](C(C)C)C(C)C4(C)C)C1=O)C(C)(C)C(C)N2C(C)C]

Dye 2: a compound having the following structure. Dye 2 is a near infrared absorbing colorant that is a compound in which a ratio D1/D2 of an absorbance D1 at a wavelength of 365 nm to a maximum value D2 of an absorbance in a wavelength range of 420 to 1000 nm is 0.6 or lower.

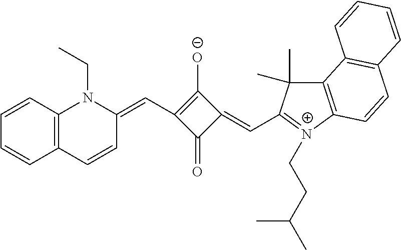 [SMILES: CCN1/C(=C/C2=C([O-])C(=C\C3=[N+](CCC(C)C)c4ccc5ccccc5c4C3(C)C)/C2=O)C=Cc2ccccc21]

PR254: C. I. Pigment Red 254 (a red colorant, a compound in which a ratio D1/D2 of an absorbance D1 at a wavelength of 365 nm to a maximum value D2 of an absorbance in a wavelength range of 420 to 1000 nm is 0.6 or lower)

PV23: C. I. Pigment Violet 23 (a violet colorant that is a compound in which a ratio D1/D2 of an absorbance D1 at a wavelength of 365 nm to a maximum value D2 of an absorbance in a wavelength range of 420 to 1000 nm is 0.6 or lower)

PY139: C. I. Pigment Yellow 139 (a yellow colorant, a compound in which a ratio D1/D2 of an absorbance D1 at a wavelength of 365 nm to a maximum value D2 of an absorbance in a wavelength range of 420 to 1000 nm is 0.6 or lower)

PBk 31: C. I. Pigment Black 31 (an organic black compound, a perylene compound, a compound in which a ratio D1/D2 of an absorbance D1 at a wavelength of 365 nm to a maximum value D2 of an absorbance in a wavelength range of 420 to 1000 nm is 0.6 or lower)

PBk 32: C. I. Pigment Black 32 (an organic black compound, a perylene compound, a compound in which a ratio D1/D2 of an absorbance D1 at a wavelength of 365 nm to a maximum value D2 of an absorbance in a wavelength range of 420 to 1000 nm is 0.6 or lower)

Black coloring material: a mixture of the following compounds (an organic black compound, a perylene compound, a compound in which a ratio D1/D2 of an absorbance D1 at a wavelength of 365 nm to a maximum value D2 of an absorbance in a wavelength range of 420 to 1000 nm is 0.6 or lower)

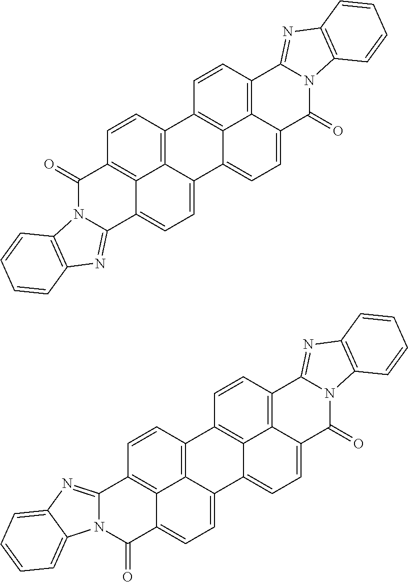 [SMILES: O=c1c2ccc3c4ccc5c6c(ccc(c7ccc(c2c37)c2nc3ccccc3n12)c46)c(=O)n1c2ccccc2nc51 ; O=c1c2ccc3c4ccc5c(=O)n6c7ccccc7nc6c6ccc(c7ccc(c2c37)c2nc3ccccc3n12)c4c56]

PB15:6: C. I. Pigment Blue 15:6 (a blue colorant, a phthalocyanine compound, a compound in which a ratio D1/D2 of an absorbance D1 at a wavelength of 365 nm to a maximum value D2 of an absorbance in a wavelength range of 420 to 1000 nm is higher than 0.6)

IB: IRAGAPHOR BLACK (an organic black colorant, a bisbenzofuranone compound, a compound in which a ratio D1/D2 of an absorbance D1 at a wavelength of 365 nm to a maximum value D2 of an absorbance in a wavelength range of 420 to 1000 nm is higher than 0.6)

(Pigment Derivative)

syn 1: a compound having the following structure

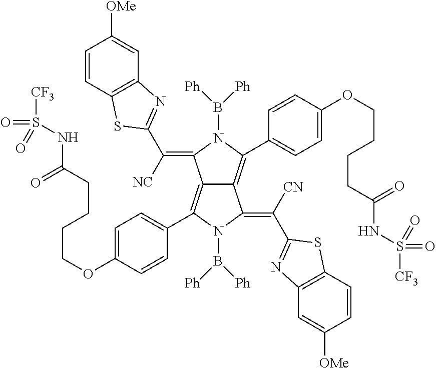 [SMILES: COc1ccc2sc(/C(C#N)=c3/c4c(-c5ccc(OCCCCC(=O)NS(=O)(=O)C(F)(F)F)cc5)n(B(c5ccccc5)c5ccccc5)/c(=C(/C#N)c5nc6cc(OC)ccc6s5)c4c(-c4ccc(OCCCCC(=O)NS(=O)(=O)C(F)(F)F)cc4)n3B(c3ccccc3)c3ccccc3)nc2c1]

(Dispersant)

A-1: a resin having the following structure (a numerical value added to a main chain represents a molar ratio, and a numerical value added to a side chain represents the number of repeating units; Mw=20,000)

A-2: a resin having the following structure (a numerical value added to a main chain represents a molar ratio, and a numerical value added to a side chain represents the number of repeating units; Mw=24,000)

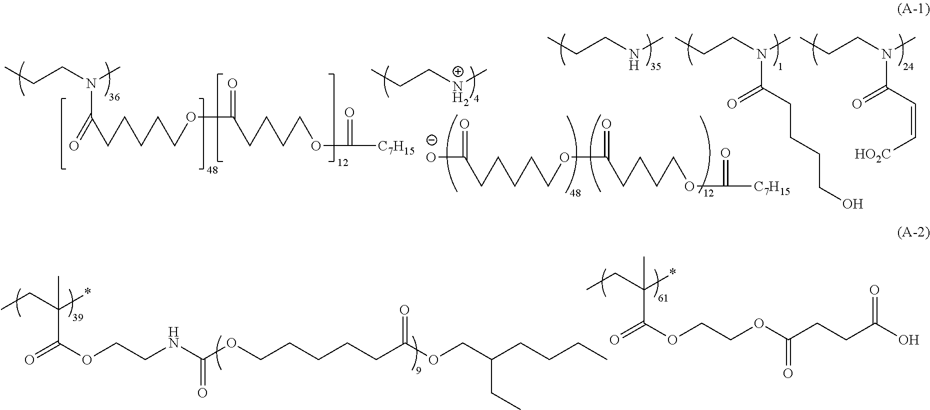

(Resin)

B-1: a resin having the following structure (Mw=11,000; a numerical value added to a main chain represents a molar ratio; Me represents a methyl group)

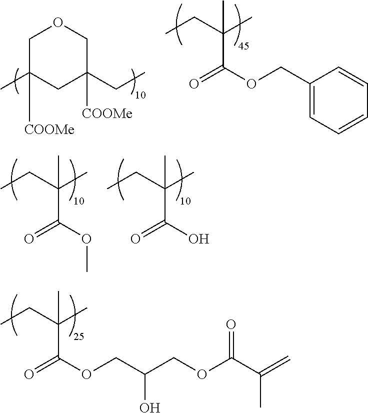

B-2: a resin having the following structure (Mw=11,000; a numerical value added to a main chain represents a molar ratio)

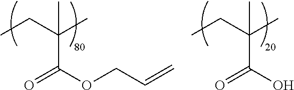

B-3: a resin having the following structure (Mw=4,400, acid value=95 mgKOH/g; in the following structural formula, M represents a phenyl group and A represents a biphenyltetracarboxylic acid anhydride residue)

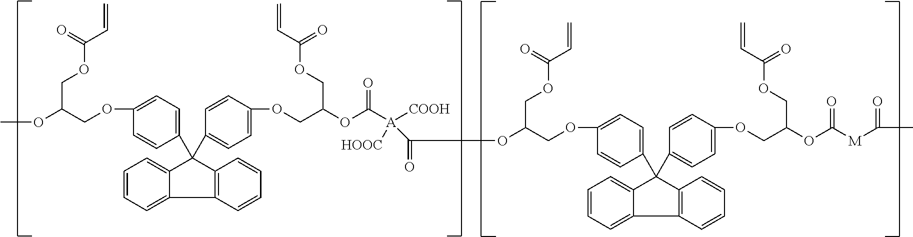

(Polymerizable Compound)

C-1: a compound having the following structure (a mixture in which a molar ratio between a left compound and a right compound is 7:3)

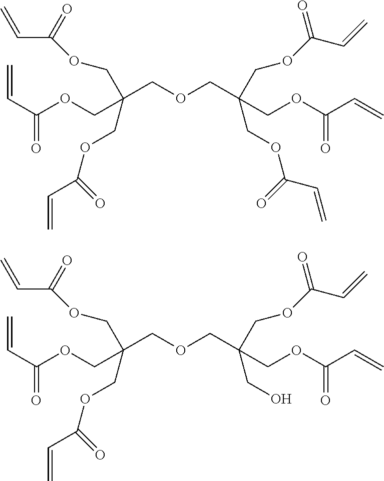

C-2: a compound having the following structure

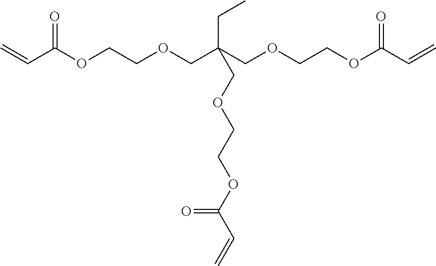 [SMILES: C=CC(=O)OCCOCC(CC)(COCCOC(=O)C=C)COCCOC(=O)C=C]

(Photopolymerization Initiator)

D-1 and D-2: compounds having the following structures

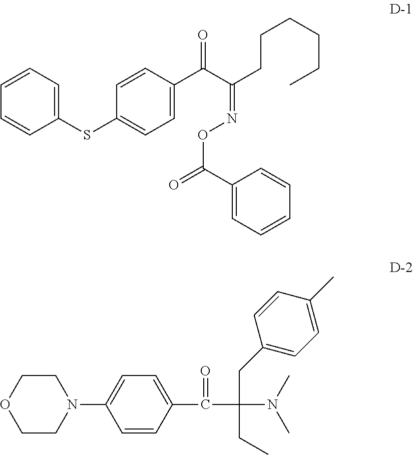 [SMILES: CCCCCC/C(=N/OC(=O)c1ccccc1)C(=O)c1ccc(Sc2ccccc2)cc1 ; CCC(Cc1ccc(C)cc1)(C(=O)c1ccc(N2CCOCC2)cc1)N(C)C]

(Surfactant)

E-1: the following mixture (Mw=14000; in the following formula, “%” representing the proportion of a repeating unit is mol %)

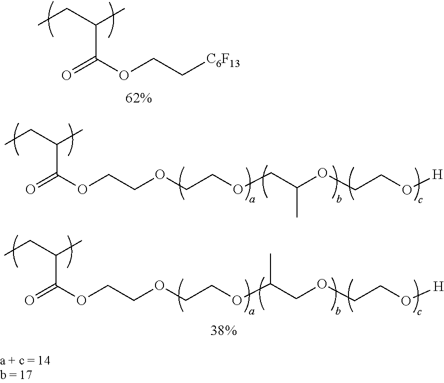

(Polymerization Inhibitor)

F-1: p-methoxyphenol

(Solvent)

S-1: propylene glycol monomethyl ether acetate (PGMEA)

S-2: cyclohexanone

<Spectral Characteristics>

Each of the curable compositions was applied to a glass substrate such that the thickness of the film after drying was as shown in the following table. Next, using an i-ray stepper exposure device FPA-i5+ (manufactured by Canon Corporation), the entire surface of the coating film was irradiated with light having a wavelength of 365 nm at an exposure dose of 1000 mJ/cm². Next, the exposed film was developed using an alkali developer (CD-2000, manufactured by Fujifilm Electronic Materials Co., Ltd.) at 25° C. for 40 seconds. Next, the developed film was rinsed with flowing water for 30 seconds, was spin-dried, and then was baked using a hot plate at 220° C. for 5 minutes to form a film. The transmittance and the absorbance of the obtained film were measured using a spectrophotometer U-4100 (manufactured by Hitachi High-Technologies Corporation). The results are shown in the following table. In the tables, an absorbance A is a minimum value of an absorbance in a wavelength range of 300 to 380 nm, an absorbance B is a minimum value of an absorbance in a wavelength range of 420 to 650 nm, and an absorbance C is a maximum value of an absorbance in a wavelength range of 1000 to 1300 nm. In addition, an absorbance ratio A/B is a ratio (absorbance kabsorbance B) of the absorbance A to the absorbance B, and an absorbance ratio B/C is a ratio (absorbance B/absorbance C) of the absorbance B to the absorbance C. In addition, a transmittance A is a maximum value of a transmittance in a wavelength range of 300 to 380 nm, a transmittance B is a maximum value of a transmittance in a wavelength range of 420 to 650 nm, and a transmittance C is a maximum value of a transmittance in a wavelength range of 1000 to 1300 nm.

<Evaluation of Adhesiveness>

CT-4000L (manufactured by Fujifilm Electronic Materials Co., Ltd.) was uniformly applied to an 8-inch (20.32 cm) silicon substrate by spin coating to form a coating film. The formed coating film was further heated using an oven at 220° C. for 1 hour to cure the coating film. As a result, an undercoat layer was formed. The rotation speed during the spin coating was adjusted such that the thickness of the heated coating film was about 0.1 μm.

Next, the curable composition obtained as described above was applied to the undercoat layer of the silicon substrate using a spin coater such that the thickness of the film after drying was as shown in the following table, and was dried using a hot plate at 100° C. for 120 seconds.

Next, using an i-ray stepper exposure device FPA-i5+(manufactured by Canon Corporation), the coating film was irradiated with light having a wavelength of 365 nm at an exposure dose of 50 to 1700 ml/cm² through a 1.0 μm×1.0 μm or 1.1 μm×1.1 μm island pattern mask. After the exposure, the exposed film was developed using an alkali developer (CD-2000, manufactured by Fujifilm Electronic Materials Co., Ltd.) at 25° C. for 40 seconds. Next, the developed film was rinsed with flowing water for 30 seconds and was dried by spraying to obtain a pattern.

The obtained pattern was observed using a scanning electron microscope (S-9220, manufactured by Hitachi, Ltd.) from above the pattern to measure the size of the pattern. In addition, adhesiveness was evaluated using an optical microscope based on the following standards.

5: the minimum size of pixels adhered to each other was 90% or lower with respect to the design dimension of the mask

4: the minimum size of pixels adhered to each other was higher than 90% and 99% or lower with respect to the design dimension of the mask

3: the minimum size of pixels adhered to each other was higher than 99% and 105% or lower with respect to the design dimension of the mask

2: the minimum size of pixels adhered to each other was higher than 105% and 110% or lower with respect to the design dimension of the mask

1: a part of the pattern exceeding 110% with respect to the design dimension of the mask was not adhered to each other

<Evaluation of Sensibility>

CT-4000L (manufactured by Fujifilm Electronic Materials Co., Ltd.) was uniformly applied to an 8-inch (20.32 cm) silicon substrate by spin coating to form a coating film. The formed coating film was further heated using an oven at 220° C. for 1 hour to cure the coating film. As a result, an undercoat layer was formed. The rotation speed during the spin coating was adjusted such that the thickness of the heated coating film was about 0.1 μm.

Next, the curable composition obtained as described above was applied to the undercoat layer of the silicon substrate using the spin coater such that the thickness of the film after drying was as shown in the following table, and was dried using a hot plate at 100° C. for 120 seconds.

Next, using an i-ray stepper exposure device FPA-i5+(manufactured by Canon Corporation), the coating film was irradiated with light having a wavelength of 365 nm at an exposure dose of 1000 mJ/cm² through a 2 μm×2 μm island pattern mask. After the exposure, the exposed film was developed using an alkali developer (CD-2000, manufactured by Fujifilm Electronic Materials Co., Ltd.) at 25° C. for 40 seconds. Next, the developed film was rinsed with flowing water for 30 seconds and was dried by spraying to obtain a pattern.

The silicon substrate on which the pattern was formed was incorporated into an optical sensor using a well-known method. In Examples 1 to 8, the ultraviolet dose in sunlight was able to be detected, and distance sensing using near infrared light was also able to be performed. In Comparative Examples 1 to 3, the ultraviolet dose in sunlight was not able to be detected. In addition, in a case where Examples 1 to 8 were industrially used, inspection of scratches and unevenness of product using ultraviolet light and inspection of foreign matter using infrared light were able to be performed simultaneously.

TABLE 3

| | | | | | | | | | Compar- | Compar- | Compar- |
|---|---|---|---|---|---|---|---|---|---|---|---|
| | Exam- | Exam- | Exam- | Exam- | Exam- | Exam- | Exam- | Exam- | ative | ative | ative |
| | ple 1 | ple 2 | ple 3 | ple 4 | ple 5 | ple 6 | ple 7 | ple 8 | Example 1 | Example 2 | Example 3 |
| Thick- | 1.0 | 1.2 | 1.2 | 1.2 | 1.5 | 1.5 | 1.5 | 1.8 | 0.8 | 1.5 | 1.0 |
| ness of | | | | | | | | | | | |
| film (μm) | | | | | | | | | | | |
| Absorb- | 0.56 | 0.63 | 0.63 | 0.63 | 0.57 | 0.57 | 0.57 | 0.80 | 0.91 | 1.25 | 1.24 |
| ance A | | | | | | | | | | | |
| Absorb- | 1.09 | 1.00 | 1.00 | 1.00 | 0.89 | 0.96 | 0.88 | 1.14 | 0.49 | 1.28 | 1.12 |
| ance B | | | | | | | | | | | |
| Absorb- | 0.02 | 0.03 | 0.03 | 0.03 | 0.03 | 0.03 | 0.03 | 0.03 | 0.02 | 0.04 | 0.04 |
| ance C | | | | | | | | | | | |
| Absorb- | 0.51 | 0.63 | 0.63 | 0.63 | 0.64 | 0.59 | 0.65 | 0.70 | 1.86 | 0.98 | 1.10 |
| ance | | | | | | | | | | | |
| ratio A/B | | | | | | | | | | | |
| Absorb- | 60.22 | 35.01 | 35.01 | 35.01 | 33.26 | 35.74 | 32.76 | 39.76 | 23.17 | 34.37 | 30.93 |
| ance | | | | | | | | | | | |
| ratio B/C | | | | | | | | | | | |
| Trans- | 27.80 | 23.62 | 23.62 | 23.62 | 26.88 | 26.88 | 26.88 | 15.84 | 12.25 | 5.63 | 5.78 |
| mittance | | | | | | | | | | | |
| A (%) | | | | | | | | | | | |
| Trans- | 8.16 | 10.04 | 10.04 | 10.04 | 12.78 | 10.96 | 13.18 | 7.23 | 32.30 | 5.31 | 7.54 |
| mittance | | | | | | | | | | | |
| B (%) | | | | | | | | | | | |
| Trans- | 95.92 | 93.65 | 93.65 | 93.65 | 94.00 | 94.00 | 94.00 | 93.61 | 95.24 | 91.81 | 91.98 |
| mittance | | | | | | | | | | | |
| C (%) | | | | | | | | | | | |
| Adhesive- | 5 | 5 | 5 | 5 | 5 | 5 | 5 | 5 | 3 | 2 | 2 |
| ness | | | | | | | | | | | |

As described above, in Examples 1 to 8, sensibility was higher than that of Comparative Examples 1 to 3. Further, as clearly seen from the above-described evaluation results, in Examples 1 to 8, adhesiveness was higher than that of Comparative Examples 1 to 3.

Even in a case where the curable composition according to each of Examples was applied to a glass substrate instead of a silicon substrate to form a film, the same effects as described above were obtained.

### Test Example

A composition for forming a near infrared cut filter was applied to a silicon substrate using a spin coating method such that the thickness of the formed film was 0.5 μm. Next, the coating film was heated using a hot plate at 100° C. for 2 minutes. Next, using an i-ray stepper exposure device FPA-3000 i5+ (manufactured by Canon Corporation), the coating film was exposed through a mask having a 2 μm×2 μm Bayer pattern at an exposure dose of 1000 mJ/cm².

Next, puddle development was performed at 23° C. for 60 seconds using a tetramethylammonium hydroxide (TMAH) 0.3 mass % aqueous solution. Next, the coating film was rinsed by spin showering. Next, the coating film was heated using a hot plate at 200° C. for 5 minutes. As a result, a 2 μm×2 μm Bayer pattern (near infrared cut filter) was formed.

Next, a Red composition was applied to the Bayer pattern of the near infrared cut filter using a spin coating method such that the thickness of the formed film was 0.5 μm. Next, the coating film was heated using a hot plate at 100° C. for 2 minutes. Next, using an i-ray stepper exposure device FPA-3000 i5+(manufactured by Canon Corporation), the coating film was exposed through a 2 μm×2 μm island pattern mask at an exposure dose of 1000 mJ/cm². Next, puddle development was performed at 23° C. for 60 seconds using a tetramethylammonium hydroxide (TMAH) 0.3 mass % aqueous solution. Next, the coating film was rinsed by spin showering. Next, the coating film was heated using a hot plate at 200° C. for 5 minutes. As a result, the Red composition was patterned on the Bayer pattern of the near infrared cut filter. Likewise, a Green composition and a Blue composition were sequentially patterned to form red, green, and blue color patterns.

Next, the curable composition of Example 1 was applied to the pattern-formed film using a spin coating method such that the thickness of the formed film was 1.0 μm. Next, the coating film was heated using a hot plate at 100° C. for 2 minutes. Next, using an i-ray stepper exposure device FPA-3000 i5+ (manufactured by Canon Corporation), the coating film was exposed through a 2 μm×2 μm island pattern mask at an exposure dose of 1000 mJ/cm². Next, puddle development was performed at 23° C. for 60 seconds using a tetramethylammonium hydroxide (TMAH) 0.3 mass % aqueous solution. Next, the coating film was rinsed by spin showering. Next, the coating film was heated using a hot plate at 200° C. for 5 minutes. As a result, the infrared transmitting filter was patterned on a portion where the Bayer pattern of the near infrared cut filter was not formed. This filter was incorporated into an optical sensor using a well-known method.

The Red composition, the Green composition, the Blue composition, and the composition for forming a near infrared cut filter used in Test Example are as follows.

(Red Composition)

The following components were mixed and stirred, and the obtained mixture was filtered through a nylon filter (manufactured by Pall Corporation) having a pore size of 0.45 μm to prepare a Red composition.

Red Pigment Dispersion Liquid . . . 51.7 parts by mass

Resin 104 . . . 0.6 parts by mass.

Polymerizable Compound 104 . . . 0.6 parts by mass

Photopolymerization Initiator 101 . . . 0.4 parts by mass

Surfactant 101 . . . 4.2 parts by mass

Ultraviolet Absorber (UV-503, manufactured by Daito Chemical Co., Ltd.) . . . 0.3 parts by mass

PGMEA . . . 42.6 parts by mass

(Green Composition)

The following components were mixed and stirred, and the obtained mixture was filtered through a nylon filter (manufactured by Pall Corporation) having a pore size of 0.45 μm to prepare a Green composition.

Green Pigment Dispersion Liquid . . . 73.7 parts by mass

Resin 104 . . . 0.3 parts by mass

Polymerizable Compound 101 . . . 1.2 parts by mass

Photopolymerization Initiator 101 . . . 0.6 parts by mass

Surfactant 101 . . . 4.2 parts by mass

Ultraviolet Absorber (UV-503, manufactured by Daito Chemical Co., Ltd.) . . . 0.5 parts by mass

PGMEA . . . 19.5 parts by mass

(Blue Composition)

The following components were mixed and stirred, and the obtained mixture was filtered through a nylon filter (manufactured by Pall Corporation) having a pore size of 0.45 μm to prepare a Blue composition.

Blue Pigment Dispersion Liquid . . . 44.9 parts by mass

Resin 104 . . . 2.1 parts by mass

Polymerizable Compound 101 . . . 1.5 parts by mass

Polymerizable Compound 104 . . . 0.7 parts by mass

Photopolymerization Initiator 101 . . . 0.8 parts by mass

Surfactant 101 . . . 4.2 parts by mass

Ultraviolet Absorber (UV-503, manufactured by Daito Chemical Co., Ltd.) . . . 0.3 parts by mass

PGMEA . . . 45.8 parts by mass

(Composition for Forming Near Infrared Cut Filter)

Dispersion Liquid IR-1 . . . 60 parts by mass

Polymerizable Compound 101 . . . 6 parts by mass

Resin 101 . . . 4.45 parts by mass

Photopolymerization Initiator 101 . . . 1.99 parts by mass

Surfactant 101 . . . 4.17 parts by mass

Polymerization Inhibitor 1 (p-methoxyphenol) . . . 0.003 parts by mass

PGMEA . . . 23.39 parts by mass

Raw materials used in the Red composition, the Green composition, the Blue composition, and the composition for forming a near infrared cut filter were as follows.

Red Pigment Dispersion Liquid

A mixed solution of 9.6 parts by mass of C. I. Pigment Red 254, 4.3 parts by mass of C. I. Pigment Yellow 139, 6.8 parts by mass of a dispersant (Disperbyk-161, manufactured by BYK Chemie), and 79.3 parts by mass of PGMEA was mixed and dispersed using a beads mill (zirconia beads; diameter: 0.3 mm) for 3 hours. As a result, a pigment dispersion liquid was prepared. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersing treatment was repeated 10 times. As a result, a Red pigment dispersion liquid was obtained.

Green Pigment Dispersion Liquid

A mixed solution of 6.4 parts by mass of C. I. Pigment Green 36, 5.3 parts by mass of C. I. Pigment Yellow 150, 5.2 parts by mass of a dispersant (Disperbyk-161, manufactured by BYK Chemie), and 83.1 parts by mass of PGMEA was mixed and dispersed using a beads mill (zirconia beads; diameter: 0.3 mm) for 3 hours. As a result, a pigment dispersion liquid was prepared.

Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersing treatment was repeated 10 times. As a result, a Green pigment dispersion liquid was obtained.

Blue Pigment Dispersion Liquid

A mixed solution of 9.7 parts by mass of C. I. Pigment Blue 15:6, 2.4 parts by mass of C. I. Pigment Violet 23, 5.5 parts by mass of a dispersant (Disperbyk-161, manufactured by BYK Chemie), and 82.4 parts by mass of PGMEA was mixed and dispersed using a beads mill (zirconia beads; diameter: 0.3 mm) for 3 hours. As a result, a pigment dispersion liquid was prepared. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2000 kg/cm³ at a flow rate of 500 g/min. This dispersing treatment was repeated 10 times. As a result, a Blue pigment dispersion liquid was obtained.

Dispersion Liquid 1R-1: Dispersion Liquid IR-1 described above.

Polymerizable Compound 101: KAYARAD DPHA (manufactured by Nippon Kayaku Co., Ltd.)

Polymerizable Compound 104: a compound having the following structure

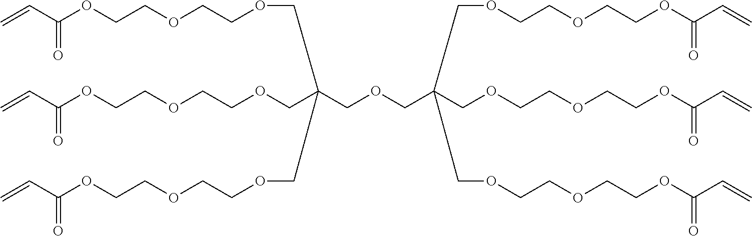 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 101: CYCLOMER P (ACA) 230AA (manufactured by Daicel Corporation)

Resin 104: a resin having the following structure (acid value: 70 mgKOH/g, Mw=11000; a ratio in a structural unit is a molar ratio)

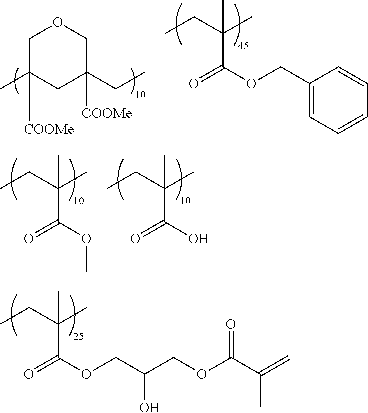

Photopolymerization Initiator 101: IRGACURE-OXE 01 (manufactured by BASF SE)

Surfactant 101: a 1 mass % PGMEA solution of the following mixture (Mw: 14000; in the following formula, “%” representing the proportion of a repeating unit is mol %)

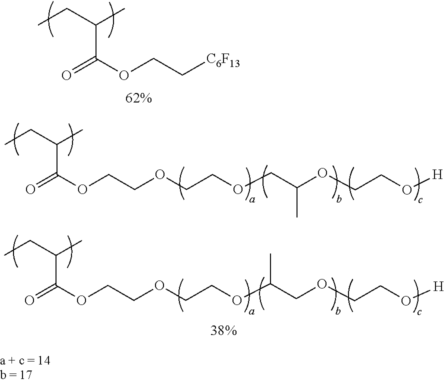

### EXPLANATION OF REFERENCES

110: solid image pickup element
111: near infrared cut filter
112: color filter
114: infrared transmitting filter
115: microlens
116: planarizing layer

What is claimed is:

1. A curable composition comprising:
a coloring material; and
a curable compound,
wherein a ratio A/B of a minimum value A of an absorbance of the curable composition in a wavelength range of 300 to 380 nm to a minimum value B of an absorbance of the curable composition in a wavelength range of 420 to 650 nm is 0.8 or lower,
a ratio B/C of the minimum value B of the absorbance of the curable composition in a wavelength range of 420 to 650 nm to a maximum value C of an absorbance of the curable composition in a wavelength range of 1000 to 1300 nm is 4.5 or higher,
a content of a compound in which a ratio D1/D2 of an absorbance D1 at a wavelength of 365 nm to a maximum value D2 of an absorbance in a wavelength range of 420 to 1000 nm is 0.6 or lower in the coloring material is 95 mass % or higher with respect to a total mass of the coloring material, and
a content of the coloring material is 20 to 70 mass % with respect to a total solid content of the curable composition.

2. The curable composition according to claim 1,
wherein a content of a phthalocyanine compound is 5 mass % or lower with respect to the total mass of the coloring material.

3. The curable composition according to claim 1,
wherein a content of a blue colorant is 5 mass % or lower with respect to the total mass of the coloring material.

4. The curable composition according to claim 1,
wherein the coloring material includes one or more colors of chromatic colorants.

5. The curable composition according to claim 1,
wherein the coloring material includes a red colorant.

6. The curable composition according to claim 1,
wherein the coloring material includes a perylene compound.

7. The curable composition according to claim 1,
wherein the coloring material includes a near infrared absorbing colorant.

8. The curable composition according to claim 1, further comprising:
a polymerizable compound; and
a photopolymerization initiator.

9. A film which is obtained using the curable composition claim 1.

10. An infrared transmitting filter comprising:
the film according to claim 9.

11. A solid image pickup element comprising:
the film according to claim 9.

12. An optical sensor comprising:
the film according to claim 9.

13. A film comprising:
20 to 70 mass % of a coloring material,
wherein a content of a compound in which a ratio D1/D2 of an absorbance D1 at a wavelength of 365 nm to a maximum value D2 of an absorbance in a wavelength range of 420 to 1000 nm is 0.6 or lower in the coloring material is 95 mass % or higher with respect to a total mass of the coloring material,
a maximum value of a transmittance in a wavelength range of 300 to 380 nm is 10% or higher,
a maximum value of a transmittance in a wavelength range of 420 to 650 nm is 20% or lower, and
a maximum value of a transmittance in a wavelength range of 1000 to 1300 nm is 70% or higher.
